(19) United States
(12) Patent Application Publication
(10) Pub. No.: US 2013/0001787 A1
(43) Pub. Date: Jan. 3, 2013

(54) SEMICONDUCTOR DEVICE AND PRODUCTION METHOD THEREFOR

(75) Inventors: Kazutaka Yoshizawa, Kuwana (JP); Taiji Ema, Inabe-gun (JP)

(73) Assignee: FUJITSU SEMICONDUCTOR LIMITED, Yokohama-shi (JP)

(21) Appl. No.: 13/447,913

(22) Filed: Apr. 16, 2012

(30) Foreign Application Priority Data
Jun. 30, 2011 (JP) 2011-146284

(51) Int. Cl. H01L 23/498; H01L 21/283

(52) U.S. Cl. 257/762; 438/687; 257/E23.072; 257/E21.159

(57) ABSTRACT

A semiconductor device includes: a semiconductor substrate; a semiconductor element formed on the semiconductor substrate; a first metal ring surrounding the semiconductor element; an insulation film formed to cover the semiconductor element and having the first metal ring disposed therein; and a groove formed in the insulation film; wherein: the first metal ring is formed by laminating multiple metal layers in such a manner that respective outside lateral faces of the multiple metal layers are flush with each other, or that outside lateral face of each of the multiple metal layers which is positioned above an underlying metal layer is positioned more inside than outside lateral face of the underlying metal layer; and the groove has first bottom which is disposed inside the first metal ring and extending to a depth of upper surface of an uppermost metal layer of the first metal ring.

### CROSS-REFERENCE TO RELATED APPLICATION

This application is based upon and claims the benefit of priority of the prior Japanese Patent Application No. 2011-146284, filed on Jun. 30, 2011, the entire contents of which are incorporated herein by reference.

### FIELD

The embodiments discussed herein are related to a semiconductor device and a production method therefor.

### BACKGROUND

Many semiconductor chips are formed along scribe line areas on a semiconductor wafer. The semiconductor wafer is sawn along the scribe line areas, to be separated into individual semiconductor chips. If a crack generated in a scribe line area at the time of sawing propagates into a semiconductor chip, the semiconductor chip is broken.

Usually a semiconductor chip has a moisture-proof ring formed along the edges thereof. Techniques in which a metal ring for inhibiting the crack propagation into the semiconductor chip is further formed outside the moisture-proof ring, are proposed (for example, see JP 2008-270720 A). With respect to the metal ring for inhibiting the crack propagation, a technique for further enhancing the effect of inhibiting the crack propagation is desired.

### SUMMARY

According to one aspect of the present invention, a semiconductor device includes: a semiconductor substrate; a semiconductor element formed on the semiconductor substrate; a first metal ring surrounding the semiconductor element; an insulation film formed to cover the semiconductor element and having the first metal ring disposed therein; and a groove formed in the insulation film; wherein: the first metal ring is formed by laminating multiple metal layers in such a manner that respective outside lateral faces of the multiple metal layers are flush with each other, or that outside lateral face of each of the multiple metal layers which is positioned above an underlying metal layer is positioned more inside than outside lateral face of the underlying metal layer; and the groove has first bottom which is disposed inside the first metal ring and extending to a depth of upper surface of an uppermost metal layer of the first metal ring.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a plan view schematically illustrating a semiconductor wafer provided with a crack prevention ring structure as an example of this invention.

FIGS. 2A to 2G are schematic sectional views in the thickness direction illustrating a main production process for a semiconductor wafer provided with the crack prevention ring structure of a first example.

FIG. 3 is a schematic sectional view in the thickness direction illustrating a state where the semiconductor wafer provided with the crack prevention ring structure of the first example is cut by a dicing saw (a case where a crack is terminated on the upper surface of the crack prevention ring).

FIG. 4 is a schematic sectional view in the thickness direction illustrating a state where the semiconductor wafer provided with the crack prevention ring structure of the first example is cut by a dicing saw (a case where a crack penetrates through the crack prevention ring).

FIG. 5 is a schematic sectional view illustrating a semiconductor wafer as a modification of the first example.

FIG. 6 is a schematic sectional view in the thickness direction of a semiconductor wafer provided with the crack prevention ring structure of a second example.

FIG. 7 is a schematic sectional view in the thickness direction of a semiconductor wafer provided with the crack prevention ring structure of a third example.

FIG. 8 is a schematic sectional view in the thickness direction of a semiconductor wafer provided with the crack prevention ring structure of a fourth example.

FIGS. 9A to 9H are schematic sectional views in the thickness direction illustrating a main production process for a semiconductor wafer provided with the crack prevention ring structure of a fifth example.

FIG. 10 is a schematic sectional view in the thickness direction of a semiconductor wafer provided with the crack prevention ring structure of a sixth example.

FIG. 11 is a schematic sectional view in the thickness direction of a semiconductor wafer provided with the crack prevention ring structure of a seventh example.

FIG. 12 is a schematic sectional view in the thickness direction of a semiconductor wafer provided with a crack prevention ring structure as an eighth example.

FIG. 13 is a schematic sectional view in the thickness direction of a semiconductor wafer provided with the crack prevention ring structure of a ninth example.

FIG. 14 is a schematic sectional view in the thickness direction of a semiconductor wafer provided with the crack prevention ring structure of a tenth example.

FIG. 15 is a schematic sectional view in the thickness direction of a semiconductor wafer provided with the crack prevention ring structure of an eleventh example.

FIG. 16 is a schematic sectional view in the thickness direction illustrating a state where the semiconductor wafer provided with the crack prevention ring structure of the eleventh example is cut by a dicing saw.

### DESCRIPTION OF EMBODIMENTS

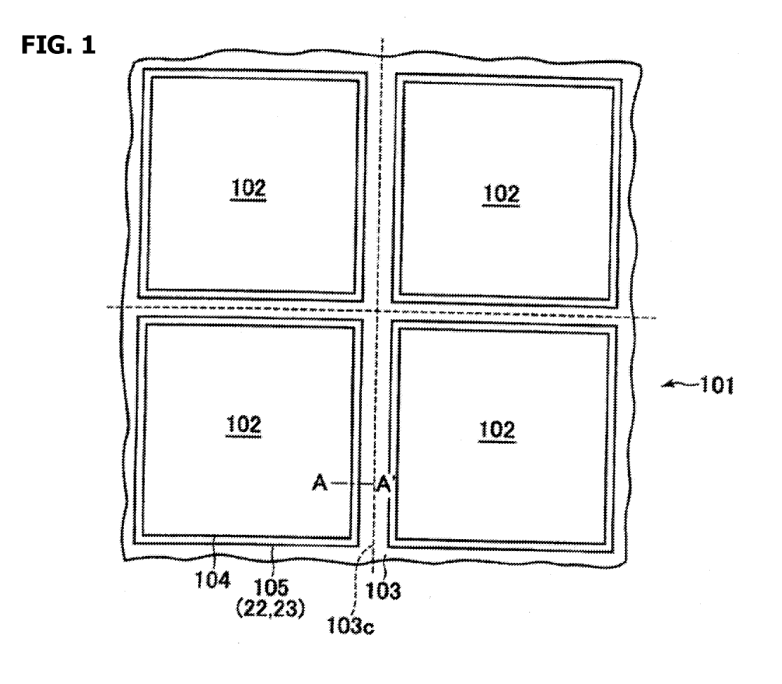

At first, in reference to FIGS. 1 to 4, the crack prevention ring structure as a first example of this invention is explained. In this description, a structure including a crack prevention ring formed by laminating metal layers, a crack prevention insulation film disposed below the crack prevention ring, and a crack prevention window formed near above the crack prevention ring is called a crack prevention ring structure.

FIG. 1 is a plan view schematically illustrating a semiconductor wafer (101) provided with the crack prevention ring structure of a first example. On the semiconductor wafer (101), multiple semiconductor chip areas are disposed in a matrix. Between the respectively adjacent semiconductor chip areas (102), scribe line areas (103) are defined. The semiconductor wafer (101) is sawn along the center lines (scribe centers) (103c) of the scribe line areas (103), to be separated into respective semiconductor chips (102).

In the outermost periphery of each semiconductor chip area (102), a crack prevention ring (105) formed like a closed loop is formed along the edges of the semiconductor chip area (102). The inside of the crack prevention ring (105) is called the semiconductor chip area (102), and the outside of the crack prevention ring (105) is called the scribe line areas (103). The crack prevention ring (105) is provided to prevent the propagation of any crack generated in a scribe line area (103) at the time of sawing the semiconductor wafer (101) into the semiconductor chip area (102).

More inside than the crack prevention ring (105) of each semiconductor chip area (102), a moisture-proof ring (104) is formed along the edges of the semiconductor chip area (102). Inside the moisture-proof ring (104), desired many semiconductor elements are formed. The size of each semiconductor chip area (102) (chip size) is, for example, approx. 5 mm square. The width of each scribe line area (103) is, for example, approx. 50 m.

Meanwhile, as described later, below the crack prevention ring (105) in the height direction, a crack prevention insulation film (22) is formed, and a crack prevention window (23) is formed near above the crack prevention ring (105). The crack prevention insulation film (22) and the crack prevention window (23) are also formed along the edges of the semiconductor chip area (102) respectively.

The process for producing the semiconductor wafer provided with the crack prevention ring structure of the first example and the structure of the crack prevention ring and the like are explained below.

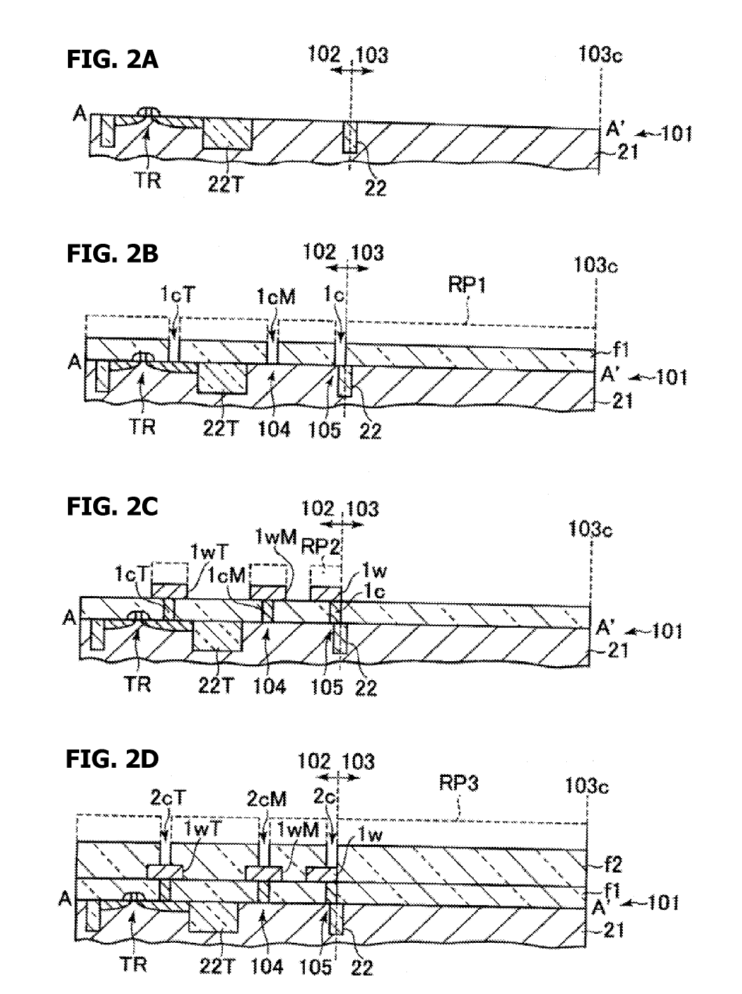

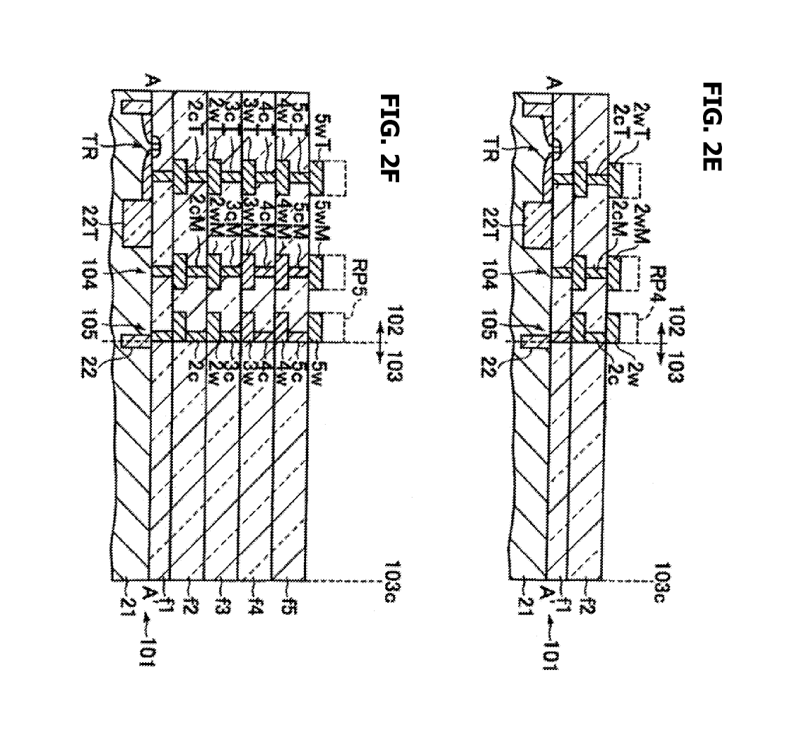

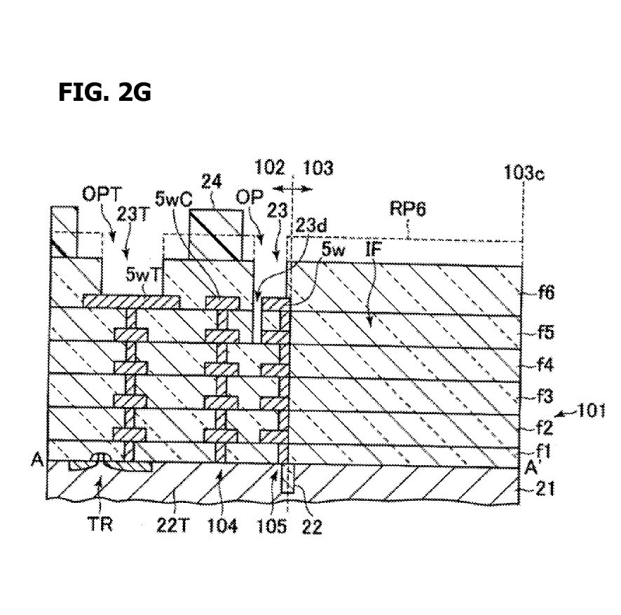

FIGS. 2A to 2G are schematic sectional views in the thickness direction illustrating the main production process for the semiconductor wafer (101) provided with the crack prevention ring structure of the first example, and illustrate the sections of the semiconductor wafer (101) along the one-dot-dash line AA′ of FIG. 1 (from the portion where a certain transistor (TR) is formed in the semiconductor chip area (102) to the scribe center (103c)). FIG. 2G illustrates the completed state of the semiconductor wafer (101).

As explained below in detail, the moisture-proof ring (104) and the crack prevention ring (105) are formed by using the process for forming the multilayer wiring connected with the transistor (TR), i.e., the process for repetitively laminating a metal layer used as a contact layer and a metal layer used as a wiring layer.

The moisture-proof ring (104) and the crack prevention ring (105) are not used as wiring, but for the convenience of explanation, each of the metal layers forming the moisture-proof ring (104) and the crack prevention ring (105) may be called a contact layer or a wiring layer. Further, the recesses for embedding the contact layers of the moisture-proof ring (104) and the crack prevention ring (105) may be called contact holes. Meanwhile, a contact hole and the contact layer embedded therein are indicated by the same reference symbol.

Further, in the following explanation, “T” is attached to the reference symbol of the metal layer portion constituting the wiring connected with the transistor (TR), and “M” is attached to the reference symbol of the metal layer portion constituting the moisture-proof ring (104), for distinguishing from the metal layer portion constituting the crack prevention ring (105).

Reference is made to FIG. 2A. An element isolation insulation film (22T) is formed in a silicon substrate (semiconductor substrate) (21) for defining the active region of the transistor (TR), for example, by shallow trench isolation (STI). At the same time, the step of forming the element isolation insulation film (22T) is used to form a crack prevention insulation film (22).

The crack prevention insulation film (22) is formed below the crack prevention ring (105) as illustrated in FIG. 2G and surrounds semiconductor elements such as the transistor (TR) like the crack prevention ring (105) (on the plan view). Meanwhile, for the sake of explanation, the edge of the crack prevention ring (105) on the side of the scribe line areas (103) is set as the border between the semiconductor chip area (102) and the scribe line area (103).

Explanation of FIG. 2A is made again. The thickness of the crack prevention insulation film (22) by STI (the depth of the groove for embedding the crack prevention insulation film (22) formed in the substrate (21)) is equal to that of the element isolation insulation film (22T), and is, for example, approx. 320 nm. The width of the crack prevention insulation film (22) is, for example, approx. 1 m.

After the element isolation insulation film (22T) and the crack prevention insulation film (22) are formed, the transistor (TR) is formed on the silicon substrate (21). The transistor (TR) can be formed, as appropriate, by using a publicly known technique.

Reference is made to FIG. 2B. A first interlayer insulation film (f1) is formed on the silicon substrate (21), while covering the transistor (TR). The first interlayer insulation film (f1) is formed, for example, as described below. On the silicon substrate (21), a silicon oxide film is deposited to have a thickness of approx. 20 nm, and on the silicon oxide film, a silicon nitride film is deposited to have a thickness of approx. 80 nm. Further, on the silicon nitride film, a boron phosphosilicate glass (BPSG) film is deposited to have a thickness of approx. 1300 nm, or a silicon oxide film using tetraethoxysilane (TEOS) is deposited to have a thickness of approx. 1000 nm. Meanwhile, when the BPSG film is formed, it is preferred to perform annealing, for example, at 650 C for approx. 120 seconds.

Further, the BPSG film or the silicon oxide film using TEOS is flattened on the upper surface by chemomechanical polishing (CMP), and subsequently a silicon oxide film is further deposited to have a thickness of approx. 100 nm, to form the first interlayer insulation film (f1). For deposition of the respective films constituting the first interlayer insulation film (f1), for example, chemical vapor deposition (CVD) is used, and the thickness of the first interlayer insulation film (f1) is, for example, approx. 950 nm.

Then, on the first interlayer insulation film (f1), a resist pattern (RP1) opened in the forms of the first contact layer portion (1cT) of the wiring connected to the source/drain region of the transistor (TR), the first contact layer portion (the lowest metal layer) (1cM) of the moisture-proof ring (104) and the first contact layer portion (the lowest metal layer) (1c) of the crack prevention ring (105) is formed by photolithography.

The resist pattern (RP1) is used as a mask to etch the first interlayer insulation film (f1), for forming the contact holes (1cT), (1cM) and (1c). After forming the contact holes (1cT), (1cM) and (1c), the resist pattern (RP1) is removed.

The width of the contact hole (1cM), i.e., the width of the first contact layer portion (1cM) of the moisture-proof ring (104) embedded therein is, for example, approx. 0.25 m. Further, the width of the contact hole (1c), i.e., the width of the first contact layer portion (1c) of the crack prevention ring (105) embedded therein is, for example, approx. 0.25 m like the width of the first contact layer portion (1cM) of the moisture-proof ring (104). Meanwhile, in the following explanation, the width of a contact hole and the width of the corresponding contact layer portion may not be distinguished from each other. In the meantime, the width of the contact layer portion of the crack prevention ring (105) is not required to agree with the width of the contact layer portion of the moisture-proof ring (104). The explanation of the case where both agree with each other is made as an example.

The first contact layer portion (1c) of the crack prevention ring (105) is formed along the edges of the semiconductor chip area (102), to surround the semiconductor elements such as the transistor (TR). Further, the wiring layer portions such as the first wiring layer portion (1w) and the contact layer portions such as the second contact layer portion (2c) formed above the first contact layer portion (1c) are also formed along the edges of the semiconductor chip area (102) respectively, to surround the semiconductor elements such as the transistor (TR).

Reference is made to FIG. 2C. A Ti/TiN/W lamination film is formed on the first interlayer insulation film (f1), while covering the inner surfaces of the contact holes (1cT), (1cM) and (1c). In the case where a lamination film is expressed like this, the film of the material written on the most left side means the film formed at the lowest (substrate side). In the Ti/TiN/W lamination film, the Ti film has a thickness of, for example, approx. 30 nm, and is deposited by sputtering, and the TiN film has a thickness of, for example, approx. 20 nm, and is deposited by sputtering. The W film has a thickness of, for example, approx. 300 nm, and is deposited by CVD.

Then, the extra portions of the Ti/TiN/W lamination film are removed by CMP, to expose the upper surface of the first interlayer insulation film, thereby leaving the first contact layer portions (1cT), (1cM) and (1c) respectively in the contact holes (1cT), (1cM) and (1c).

The first contact layer portion (1c) of the crack prevention ring (105) is disposed (for example) on the crack prevention insulation film (22). In the illustrated example, on the plan view, the first contact layer portion (1c) partially overlaps the crack prevention insulation film (22), but the entire first contact layer portion (1c) can also be disposed to overlie (that is, the first contact layer portion (1c) can be disposed within the width of the crack prevention insulation film (22)). Further, the first contact layer portion (1c) can also be disposed without overlapping the crack prevention insulation film (22) (the end of the crack prevention insulation film (22) on the side of the semiconductor chip area (102) may agree with the end of the first contact layer portion (1c) on the side of the scribe line area (103), or may be positioned more on the side of the scribe line area (103) than the end of the first contact layer portion (1c) on the side of the scribe line area (103)).

However, the crack prevention insulation film (22) is disposed in such a manner that the end of the crack prevention insulation film (22) on the side of the scribe line area (103) is positioned more on the side of the scribe line area (103) than the end of the first contact layer portion (1c) as the lowest layer of the crack prevention ring (105) on the side of the scribe line area (103).

Then, a Ti/TiN/Al/Ti/TiN lamination film is formed on the first interlayer insulation film (f1), while covering the first contact layer portions (1cT), (1cM) and (1c). In the Ti/TiN/Al/Ti/TiN lamination film, the Ti film below the Al film has a thickness of, for example, approx. 60 nm, and the TiN film below the Al film has a thickness of, for example, approx. 30 nm. The Al film has a thickness of, for example, approx. 360 nm. The Ti film above the Al film has a thickness of, for example, approx. 5 nm, and the TiN film above the Al film has a thickness of, for example, approx. 70 nm (the overall thickness is approx. 525 nm). The respective films are deposited by sputtering.

Then, on the Ti/TiN/Al/Ti/TiN lamination film, a resist pattern (RP2) with the forms of first wiring layer portions (1wT), (1wM) and (1w) is formed by photolithography. The resist pattern (RP2) is used as a mask, to etch the Ti/TiN/Al/Ti/TiN lamination film, thereby leaving the first wiring layer portions (1wT), (1wM) and (1w). For the etching or the like of the Ti/TiN/Al/Ti/TiN lamination film, a publicly known aluminum wiring forming technique can be used. After forming the first wiring layer portions (1wT), (1wM) and (1w), the resist pattern (RP2) is removed.

The width of the first wiring layer portion (1wM) of the moisture-proof ring (104) is, for example, 3 m to 5 m, and the width of the first wiring layer portion (1w) of the crack prevention ring (105) is, for example, 1 m to 4 m (typically approx. 3 m).

The first wiring layer portions (1wT), (1wM) and (1w) are respectively disposed to overlap the first contact layer portion (1cT) of the wiring, the first contact layer portion (1cM) of the moisture-proof ring (104) and the first contact layer portion (1c) of the crack prevention ring (105).

In the crack prevention ring (105) of the first example, it is desirable that the first wiring layer portion (1w) overlaps the first contact layer portion (1c) in such a manner that the ends of the both the layers on the side of the scribe line area (103) accurately agree with each other. For this purpose, the position of the end of the first contact layer (1c) on the side of the scribe line area (103) is made to agree with the position of the end of the first wiring layer (1w) on the side of the scribe line area (103) in design.

Reference is made to FIG. 2D. A second interlayer insulation film (f2) is formed on the first interlayer insulation film (f1), while covering the first wiring layer portions (1wT), (1wM) and (1w). The second interlayer insulation film (f2) is formed, for example, as described below. On the first interlayer insulation film (f1), a silicon oxide film is deposited to have a thickness of approx. 750 nm by CVD, and on the silicon oxide film, a silicon oxide film using TEOS is deposited to have a thickness of approx. 1100 nm by CVD. Further, the upper surface of the silicon oxide film using TEOS is flattened by CMP, to form the second interlayer insulation film (f2). The thickness of the second interlayer insulation film (f2) is, for example, approx. 1 m, and the thickness remaining on the first wiring layer portions (1wT), (1wM) and (1w) is, for example, approx. 460 nm.

Then, on the second interlayer insulation film (f2), a resist pattern (RP3) opened in the forms of a second contact layer portion (2cT) of the wiring, a second contact layer portion (2cM) of the moisture-proof ring (104) and a second contact layer portion (2c) of the crack prevention ring (105) is formed by photolithography.

The resist pattern (RP3) is used as a mask, to etch the second interlayer insulation film (f2), for thereby forming contact holes (2cT), (2cM) and (2c). After forming the contact holes (2cT), (2cM) and (2c), the resist pattern (RP3) is removed.

The width of the second contact layer portion (2cM) of the moisture-proof ring (104) and the width of the second contact layer portion (2c) of the crack prevention ring (105) are respectively, for example, approx. 0.25 m, like the widths of the first contact layer portions (1cM) and (1c).

Reference is made to FIG. 2E. A Ti/TiN/W lamination film is formed on the second interlayer insulation film (f2), while covering the inner surfaces of the contact holes (2cT), (2cM) and (2c). In the Ti/TiN/W lamination film, the film Ti has a thickness of, for example, approx. 20 nm and is deposited by sputtering, and the TiN film has a thickness of, for example, approx. 40 nm and is deposited by sputtering. The W film has a thickness of, for example, approx. 300 nm and is deposited by CVD.

Then, the extra portions of the Ti/TiN/W lamination film are removed by CMP, to expose the second interlayer insulation film (f2), for thereby leaving second contact layer portions (2cT), (2cM) and (2c) respectively in the contact holes (2cT), (2cM) and (2c).

The second contact layer portion (2c) is disposed to overlap the first wiring layer portion (1w). In the crack prevention ring (105) of the first example, it is desirable that the second contact layer portion (2c) is formed to overlap the first wiring layer portion (1w) in such a manner that the ends of both the layers on the side of the scribe line area (103) may accurately agree with each other. For this purpose, the position of the end of the first wiring layer portion (1w) on the side of the scribe line area (103) is made to agree with the position of the end of the contact hole (2c) for having the second layer portion (2c) embedded therein on the side of the scribe line area (103) in design.

Further, in the crack prevention ring (105) of the first example, the contact layer portions and the wiring layer portions formed further as upper layers are formed in such a manner that the ends of the respective layers on the side of the scribe line area (103) may accurately agree with each other. That is, the crack prevention ring (105) of the first example is formed in such a manner that the side face thereof on the side of the scribe line area (103) may be smooth.

Then, a Ti/TiN/Al/Ti/TiN lamination film is formed on the second interlayer insulation film (f2), while covering the second contact layer portions (2cT), (2cM) and (2c). The Ti/TiN/Al/Ti/TiN lamination film is formed like the Ti/TiN/Al/Ti/TiN lamination film formed on the first interlayer insulation film (f1).

Then, on the Ti/TiN/Al/Ti/TiN lamination film, a resist pattern (RP4) with the forms of second wiring layer portions (2wT), (2wM) and (2w) is formed. The resist pattern (RP4) is used as a mask, to etch the Ti/TiN/Al/Ti/TiN lamination film, for thereby leaving the second wiring layer portions (2wT), (2wM) and (2w). After forming the second wiring layer portions (2wT), (2wM) and (2w), the resist pattern (RP4) is removed.

For example, the widths of the second wiring layer portion (2wM) of the moisture-proof ring (104) and the second wiring layer portion (2w) of the crack prevention ring (105) are respectively the same as the widths of the first wiring layer portions (1wM) and (1w). Further, as described above, the second wiring layer portion (2w) and the second contact layer portion (2c) of the crack prevention ring (105) are formed in such a manner that the ends of both the layers on the side of the scribe line area (103) may agree with each other.

Reference is made to FIG. 2F. The same process as that for forming the first wiring layer portions (1wT), (1wM) and (1w), and forming the second interlayer insulation film (f2) for covering the first wiring layer portions (1wT), (1wM) and (1w), and further forming the second contact layer portions (2cT), (2cM) and (2c) in the second interlayer insulation film (f2) is repeated to form multilayer wiring and to form the moisture-proof ring (104) and the crack prevention ring (105). In the illustrated example, up to the fifth contact layer portions (5cT), (5cM) and (5c) in the fifth interlayer insulation film (f5) as the uppermost contact layer are formed.

For example, the widths and the heights of the third to fifth contact layer portions (3cM) to (5cM) of the moisture-proof ring (104) are the same as the width and the height of the second contact layer portion (2cM). For example, the third to fifth contact layer portions (3c) to (5c) of the crack prevention ring (105) are the same as the width and height of the second contact layer portion (2c).

For example, the widths and heights of the third and fourth wiring layer portions (3wM) and (4wM) of the moisture-proof ring (104) are the same as the widths and heights of the first and second wiring layer portions (1wM) and (2wM). For example, the widths and heights of the third and fourth wiring layer portions (3w) and (4w) of the crack prevention ring (105) are the same as the widths and heights of the first and second wiring layer portions (1w) and (2w).

Further, a Ti/TiN/Al/TiN lamination film as the uppermost metal layer is formed on the fifth interlayer insulation film (f5), while covering the fifth contact layer portions (5cT), (5cM) and (5c). In the Ti/TiN/Al/TiN lamination film, the Ti film has a thickness of, for example, approx. 60 nm, and the TiN film below the Al film has a thickness of, for example, approx. 30 nm. The Al film has a thickness of, for example, approx. 700 nm and the TiN film above the Al film has a thickness of, for example, approx. 70 nm (the overall thickness is approx. 860 nm). The respective films are deposited by sputtering.

Then, on the Ti/TiN/Al/TiN lamination film, a resist pattern (RP5) with the forms of the fifth wiring layer portions (5wT), (5wM) and (5w) is formed by photolithography. The resist pattern (RP5) is used as a mask, to etch the Ti/TiN/Al/TiN lamination film, for thereby leaving the fifth wiring layer portions (5wT), (5wM) and (5w). After forming the fifth wiring layer portions (5wT), (5wM) and (5w), the resist pattern (RP5) is removed.

For example, the width of the fifth wiring layer portion (5wM) of the moisture-proof ring (104) is 3 m to 5 m like the lower wiring layer portions (1wM, etc.). For example, the width of the fifth wiring layer portion (5w) of the crack prevention ring (105) is 1 m to 4 m (typically approx. 3 m) like the lower wiring layer portions (1w, etc.).

In this way, a multilayer wiring forming process (and a moisture-proof ring (104) forming process) is used to form the crack prevention ring (105) of the first example. As described above, the crack prevention ring (105) of the first example is formed in such a manner that the lateral surface on the side of the scribe line area (103) may be flat.

The crack prevention ring (105) is formed to avoid the contact with the moisture-proof ring (104). That is, the crack prevention ring (105) and the moisture-proof ring (104) are formed in such a manner that the wiring layer portion ends of both the rings facing each other may have a certain clearance between them. The distance between the wiring layer portion end of the moisture-proof ring (104) and the wiring layer portion end of the crack prevention ring (105) is, for example, approx. 2 m (maximum approx. 5 m).

Reference is made to FIG. 2G. A cover insulation film (f6) is formed on the fifth interlayer insulation film (f5), while covering the fifth wiring layer portions (5wT), (5wM) and (5w). For example, the cover insulation film (f6) is formed by depositing a silicon oxide film to have a thickness of approx. 700 nm on the fifth interlayer insulation film (f5) by CVD, and depositing a silicon nitride film to have a thickness of approx. 700 nm on the silicon oxide film by CVD.

Then, on the cover insulation film (f6), a resist pattern (RP6) is formed by photolithography. The resist pattern (RP6) has an opening (OPT) with a form of a contact window (pad window) (23T) and an opening (OP) with a form of a crack prevention window (23). The opening (OPT) is formed on the upper surface of the wiring layer portion (5wT) of the multilayer wiring. The opening (OP) is formed on the wiring layer portion (5w) on the side of the scribe line area (103) and extends outside the wiring layer portion (5w) on the side of the semiconductor chip area (102).

The resist pattern (RP6) is used as a mask, to etch the cover insulation film (f6) and the like, for thereby forming the contact window (23T) and the crack prevention window (23) (groove (23)). Like this, the crack prevention window (23) can be formed by using the step of forming the contact window (23T) for the wiring. For example, the etching for forming the contact window (23T) is performed using a mixed gas obtained by combining CF₄, CHF₃, Ar and the like, and is usually performed under over-etching conditions. After forming the contact window (23T) and the crack prevention window (23), the resist pattern (RP6) is removed.

In the portion where the contact window (23T) is formed, the cover insulation film (f6) is etched to expose the wiring layer portion (5wT) at the bottom, for forming the contact window (23T). In the portion where the crack prevention window (23) is formed, the portion lying on the wiring layer portion (5w) reveals the upper surface of the wiring layer portion (5w) at the bottom, not allowing further exposure even if over-etching is performed. On the other hand, in the portion (23d) outside the wiring layer portion (5w) (on the side of the semiconductor chip area (102)), the laminated insulation film (IF) is dug by over-etching to a depth deeper than the upper layer of the wiring layer portion (5w).

In the example illustrated in FIG. 2G, the cover insulation film (f6) and the fifth interlayer insulation film (f5) are etched, and the bottom of the crack prevention window (23) reaches the upper layer of the fourth interlayer insulation film (f4). Meanwhile, the depth of the crack prevention window (23) can be adjusted as required.

As described above, the crack prevention window (23) is formed. The crack prevention window (23) exposes the upper surface of the wiring layer (5w) in a portion of the scribe line area (103) side and reaches the halfway height of the crack prevention ring (105) in a portion of the semiconductor chip area (102) side. The portion (23d) dug to the halfway height of the crack prevention ring (105) on the side of the semiconductor chip area (102) may be called the dug portion (23d) of the crack prevention window (23).

The overall width of the crack prevention window (23) is, for example, approx. 1 m to approx. 3 m. The width of the wiring layer portion (5w) on which the crack prevention window (23) is formed is, for example, approx. 0.5 m, and the width of the dug portion (23d) is, for example, approx. 1.0 m.

On the plan view, the crack prevention window (23) is formed on the crack prevention ring (105) along the edge of the semiconductor chip area (102), and surrounds the semiconductor elements such as the transistor (TR). The crack prevention window (23) separates the cover insulation film (f6) covering the uppermost metal layer portion (5w) of the crack prevention ring (105) into the side of the semiconductor chip area (102) and the side of the scribe line area (103).

Subsequently as required, an insulation film (24) of a polyimide or the like is formed on the cover insulation film (f6). The insulation film (24) is formed as a pattern to expose the contact window (23T) and to refrain from going beyond the moisture-proof ring (104) toward the side of the scribe line area (103). That is, the insulation film (24) does not interfere with the crack prevention window (23).

As described above, the semiconductor wafer (101) provided with the crack prevention ring structure of the first example can be formed. Meanwhile, the number of layers of the multilayer wiring, that is, the number of metal layers forming the crack prevention ring can be changed as appropriate in response to the type of semiconductor chips.

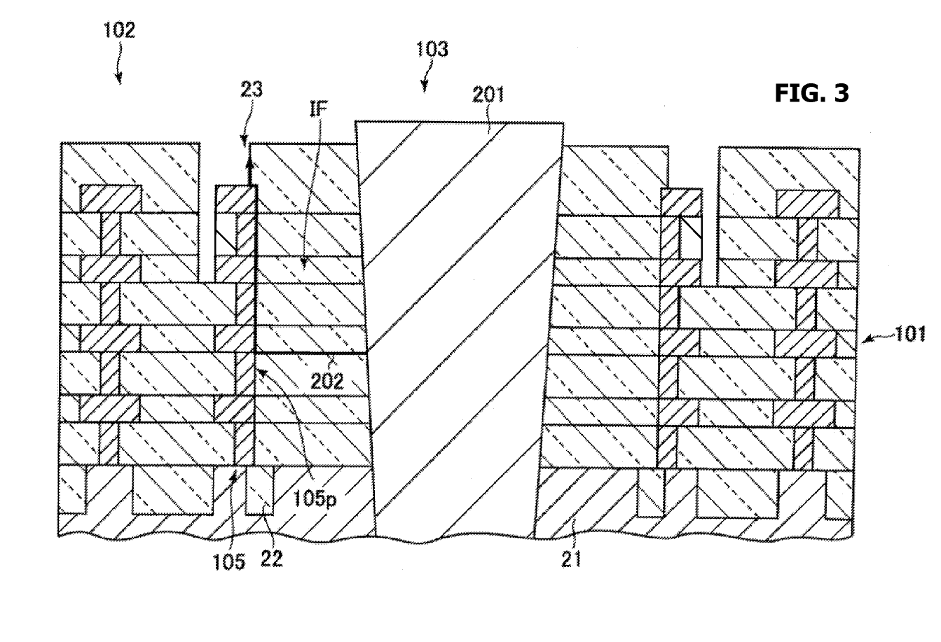

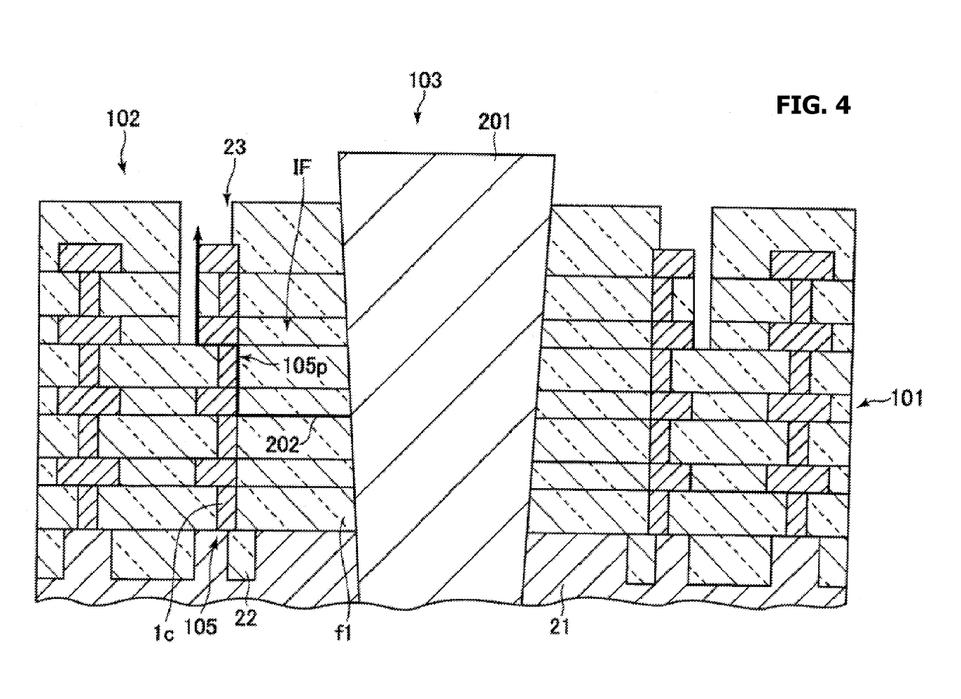

In reference to FIGS. 3 and 4, the function of the crack prevention ring structure of the first example is explained. FIGS. 3 and 4 are schematic sectional views in the thickness direction of states where the semiconductor wafer (101) provided with the crack prevention ring structure of the first example is cut by a dicing saw (201).

FIG. 3 illustrates an example of the case where a crack (202) propagates from near the dicing saw (201) toward the semiconductor chip area (102) along the interface between laminated interlayer insulation films. The propagation path of the crack (202) is indicated by an arrow.

The crack (202) generated near the dicing saw (201) and propagating in the transverse direction (in-plane direction) reaches the lateral surface (105p) of the crack prevention ring (105) on the side of the scribe line area (103). If the crack (202) reaches the lateral surface (105p), the propagation direction of the crack (202) changes into the vertical direction (thickness direction), and the crack (202) propagates along the interface between the crack prevention ring (105) and the laminated insulation film (IF) (i.e., along the lateral surface (105p)).

Since the lateral surface (105p) is smoothly formed, the crack prevention ring (105) of the first example allows the crack (202) to propagate smoothly along the lateral surface (105p).

For example, as a comparative example, a crack prevention ring with a recessed and projected lateral surface in which the ends of the wiring layers on the side of the scribe line area (103) are greatly projected toward the side of the scribe line area compared with the ends of the contact layers, can be considered. If a crack is going to propagate along such a lateral surface of the crack prevention ring, the crack inevitably changes in direction along the recesses and projections. Being caused by such a directional change, the crack acts to raise the portion of each wiring layer projecting like a roof edge above the underlying contact layer, and the wiring layer is likely to be separated from the contact layer, possibly causing the crack prevention ring to be broken.

The crack prevention ring (105) of the first example is inhibited from being broken owing to the smooth lateral surface (105p) when the crack propagates.

The crack (202) propagating along the lateral surface (105p) reaches the crack prevention window (23) at the upper surface of the uppermost metal layer of the crack prevention ring (105), to terminate. As another comparative example, a case where an insulation film remains on the uppermost metal layer of the crack prevention ring without forming the crack prevention window (23), can be considered. In this case, along the interface between the upper surface of the uppermost metal layer and the insulation film, the crack is likely to propagate into the semiconductor chip area. The crack prevention window (23) terminates the crack (202) on the crack prevention ring (105), for inhibiting the invasion of the crack (202) into the semiconductor chip area (102).

As described above, the crack prevention ring (105) of the first example is inhibited from being broken owing to the smooth lateral surface (105p) when the crack propagates. However, this does not mean that there is no possibility of breaking the crack prevention ring (105).

FIG. 4 illustrates an example of the crack propagation path by an arrow in the case where the crack (202) goes through to the side of the semiconductor chip area (102) in the upper portion of the crack prevention ring (105). As in the case illustrated in FIG. 3, the crack (202) generated near the dicing saw (201) reaches the lateral surface (105p) of the crack prevention ring (105) and propagates upward along the lateral surface (105p). Further, the crack (202) penetrates through the crack prevention ring (105) between the metal layers disposed at the halfway height of the crack prevention ring (105).

However, the dug portion (23d) of the crack prevention window (23) is formed at a depth lower than the depth at which the crack (202) penetrates through the crack prevention ring (105). Owing to this configuration, the crack (202) penetrating through the crack prevention ring (105) reaches the inner surface of the crack prevention window (23), and consequently the propagation of the crack further toward the side of the semiconductor chip area (102) can be inhibited. As described here, the dug portion (23d) allows the crack (202) penetrating through the crack prevention ring (105) to be terminated easily. It is preferred that the depth of the dug portion (23d) is below the lower surface of the uppermost metal layer of the crack prevention ring (105).

Meanwhile, the crack prevention insulation film (22) has the following function. The end of the crack prevention insulation film (22) on the side of the scribe line area (103) is disposed more on the side of the scribe line area (103) than the end of the lowermost metal layer of the crack prevention ring (105) on the side of the scribe line area (103). The crack that generates near the dicing saw (201) and propagates in the transverse direction at the height corresponding to the surface layer portion of the substrate (21) reaches the lateral face of the crack prevention insulation film (22) on the side of the scribe line area (103). Thereafter, the crack is likely to propagate along the interface between the substrate (21) and the crack prevention insulation film (22) where stress concentration occurs, rather than propagating into the crack prevention insulation film (22).

The crack that propagates along the interface between the substrate (21) and the crack prevention insulation film (22) and reaches the surface of the substrate further propagates along the interface between the crack prevention insulation film (22) and the lowest interlayer insulation film (along the upper surface of the crack prevention insulation film (22)), being guided to the lowest portion of the lateral surface (105p) of the crack prevention ring (105). Subsequently, as explained in reference to FIGS. 3 and 4, the crack is guided upward along the lateral surface (105p) of the crack prevention ring (105).

As explained above, the crack prevention ring structure of the first example can inhibit the crack generated at the time of sawing the semiconductor wafer from propagating into the semiconductor chip.

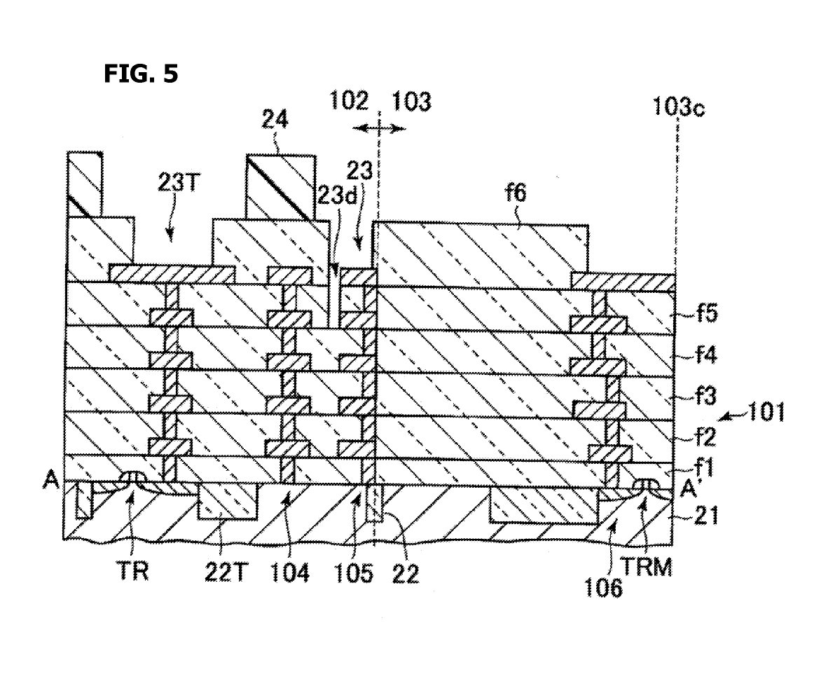

FIG. 5 is a schematic sectional view illustrating a semiconductor wafer (101) as a modification of the first example. In this modification, in the scribe line area (103), a monitor circuit (106) including a transistor (TRM) for monitoring and multilayer wiring connected therewith is formed. The monitor circuit (106) can be formed simultaneously with the circuits produced in the semiconductor chip area (102).

Meanwhile, in order to enhance the flatness in the scribe line area (103), the cover insulation film (f6) remains in the other portion than the contact window of the monitor circuit (106). In the meantime, also in the semiconductor wafers employing the crack prevention ring structures of other examples explained below, the monitor circuit can be formed.

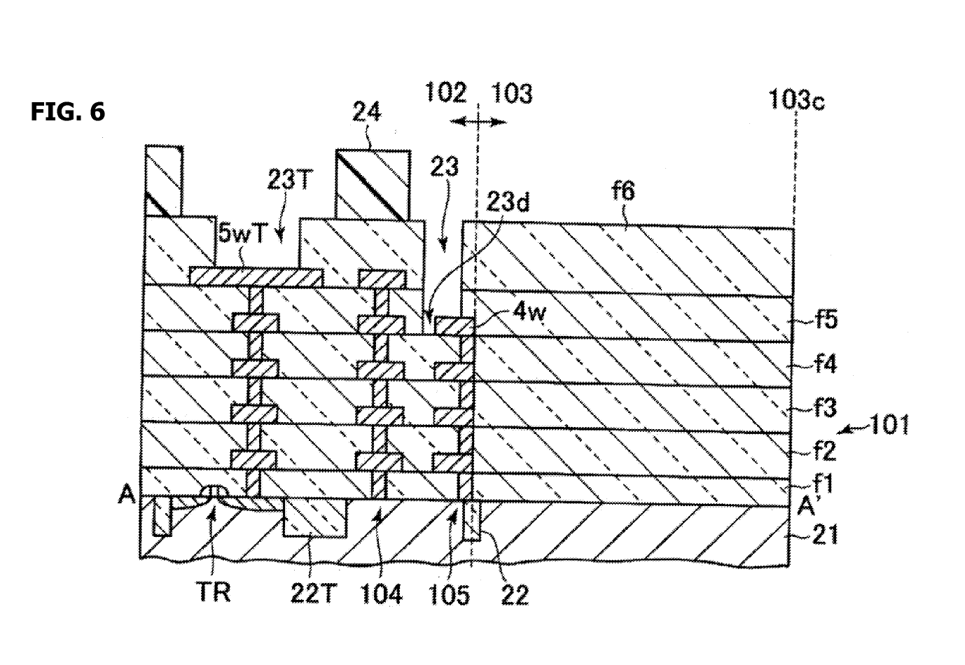

Next, in reference to FIG. 6, the crack prevention ring structure of a second example is explained.

FIG. 6 is a schematic sectional view in the thickness direction of a semiconductor wafer (101) provided with the crack prevention ring structure of a second example. The general plan structure of the semiconductor wafer (101) provided with the crack prevention ring structure of the second example is the same as that of the first example (see FIG. 1). The difference between the first and second examples is the structure of the crack prevention ring.

In the first example, the metal layers up to the metal layer portion (5w) at the same level as the uppermost metal layer portion (5wT) forming the connection wiring to the transistor (TR) are used to form the crack prevention ring (105). In the second example, the metal layers lower than the uppermost metal layer of the wiring are used to form the crack prevention ring (105). In the example illustrated in FIG. 6, the metal layer portions up to the wiring layer portion (4w) are used to form the crack prevention ring (105). Also the crack prevention ring (105) of the second example inhibits the breaking caused when a crack propagates, owing to the smooth lateral surface on the side of the scribe line area (103).

The crack prevention window (23) of the second example exposes the wiring layer portion (4w) in the portion where it is formed right above the wiring layer portion (4w) and the bottom of the crack prevention window (23) reaches the upper surface of the interlayer insulation film (f4) in the dug portion (23d) outside the wiring layer portion (4w) (on the side of the semiconductor chip area (102)). Compared with the first example, the structure of the second example omits a metal layer forming the crack prevention ring (105) in the portion above the bottom of the crack prevention window (23).

Also in the second example, the uppermost metal layer of the crack prevention ring (105) is exposed at the bottom of the crack prevention window (23), and a crack can be terminated on the uppermost metal layer of the crack prevention ring (105). Further, the dug portion (23d) is likely to terminate the crack that penetrates through the crack prevention ring (105). The invasion of the crack into the semiconductor chip area (102) can be inhibited.

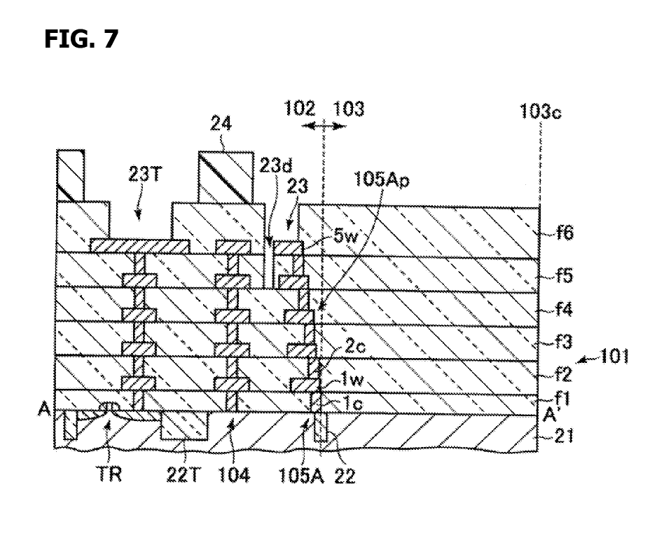

Next, in reference to FIG. 7, the crack prevention ring structure of a third example is explained.

FIG. 7 is a schematic sectional view in the thickness direction of a semiconductor wafer (101) provided with the crack prevention ring structure of a third example. The general plan structure of the semiconductor wafer (101) provided with the crack prevention ring structure of the third example is the same as that of the first example (see FIG. 1). The difference between the first and third examples is the structure of the crack prevention ring.

The crack prevention ring (105) of the first example has a smooth surface (the surface perpendicular to the substrate surface) as the lateral surface (105p) on the side of the scribe line area (103). On the other hand, the crack prevention ring (105A) of the third example has a stairway form as the lateral surface (105Ap) on the side of the scribe line area (103), and the lateral surface as a whole is inclined to approach the side of the semiconductor chip area (102) with the rise of height.

The crack prevention ring (105A) of the third example is also formed by using a multilayer wiring forming process like the crack prevention ring (105) of the first example. However, in the crack prevention ring (105A) of the third example, the metal layers are laminated one after another in such a manner that the end of each layer on the side of the scribe line area (103) may shift more toward the side of the semiconductor chip area (102) than the end of the lower metal layer on the side of the scribe line area (103).

For example, specifically, the crack prevention ring (105A) of the third example is formed as described below by partially changing the first example. The widths and heights of the first contact layer portion (1c) to the fifth contact layer portion (5c) and the first wiring layer portion (1w) to the fifth wiring layer portion (5w) of the crack prevention ring (105A) are the same as those of the crack prevention ring (105) of the first example. For example, the widths of the first contact layer portion (1c) to the fifth contact layer portion (5c) are respectively 0.25 m, and the widths of the first wiring layer portion (1w) to the fifth wiring layer portion (5w) are respectively, for example, 3 m.

As described in the first example, the first contact layer portion (1c) is formed in the first interlayer insulation film (f1). The first wiring layer portion (1w) overlapped on the first contact layer portion (1c) is disposed in such a manner that the end of the first wiring layer portion (1w) on the side of the scribe line area (103) may shift more toward the side of the semiconductor chip area (102) than the end of the first contact layer portion (1c) on the side of the scribe line area (103) by a distance corresponding to one half of the width of the first contact layer portion (1c) at the maximum (for example approx. 0.13 m or less).

Further, the second contact layer portion (2c) overlapped on the first wiring layer portion (1w) is disposed in such a manner that the end of the second contact layer portion (2c) on the side of the scribe line area (103) may shift more toward the side of the semiconductor chip area (102) than the end of the first wiring layer portion (1w) on the side of the scribe line area (103), for example, by a distance of one half of the width of the second contact layer portion (2c) at the maximum (for example approx. 0.13 m or less). In order to ensure this disposition, a contact hole (2c) for embedding the second contact layer portion (2c) therein is formed.

Subsequently likewise, each wiring layer portion is laminated on the lower contact layer portion, and each contact layer portion is laminated on the lower wiring layer portion in succession in such a manner that the end of each layer on the side of the scribe line area (103) may shift more toward the side of the semiconductor chip area (102), to form the crack prevention ring (105A) of the third example.

Meanwhile, in the crack prevention ring (105A) of the third example, the upper portion is closer to the side of the moisture-proof ring (104) than the lower portion. Accordingly, as required, the lowest first contact layer portion (1c) of the crack prevention ring (105A) of the third example is disposed more apart from the moisture-proof ring (104) than that of the first example. Further, in response to the position of the contact layer portion (1c), the crack prevention insulation film (22) is disposed.

The lateral surface (105p) of the crack prevention ring (105) of the first example is designed to be smooth and ideally finished to be perfectly flat. However, owing to the alignment error or the like during production, the actually produced lateral surface (105p) can be uneven to some extent. Meanwhile even if the unevenness due to an error occurs, the error is averaged in the entire range from the bottom to the top of the crack prevention ring (that is, averaged as a whole), and consequently the lateral surface (105p) can be said to be formed perpendicularly to the substrate surface.

As described as a comparative example (in reference to FIG. 3) for the first example, if the end of any upper metal layer overlapping the underlying lower metal layer projects greatly like a roof edge toward the side of the scribe line area (103) from the lateral surface (105p) of the crack prevention ring (105), the crack prevention ring (105) is likely to be broken when a crack propagates.

The crack prevention ring (105A) of the third example is formed like a stairway in such a manner that the upper portion of the lateral surface (105Ap) on the side of the scribe line area (103) may be closer to the semiconductor chip area (102). That is, the metal layers are disposed in such a manner that the outside lateral face of each upper metal layer may be withdrawn more toward the side of the semiconductor chip area (102) than the underlying lower metal layer. With this configuration, even if an error occurs during production, the projection like a roof edge is unlikely to occur, and the breaking of the crack prevention ring (105A) caused by the crack propagation can be inhibited more reliably.

Meanwhile, it can be considered that the crack prevention ring (105) with the lateral surface (105p) kept vertical as the first example can be easily made narrower in the installation width of the crack prevention ring than the crack prevention ring (105A) with the lateral surface (105Ap)) kept inclined as the third example.

The crack prevention window (23) of the third example exposes the wiring layer portion (5w) in the portion where it is formed right above the wiring layer portion (5w) and the bottom of the crack prevention window (23) reaches the upper surface of the interlayer insulation film (f4) in the dug portion (23d) outside the wiring layer portion (5w) (on the side of the semiconductor chip area (102)). With this configuration, also in the third example, as in the first example or the second example, the crack can be terminated on the uppermost metal layer of the crack prevention ring (105). Further, the crack that penetrates through the crack prevention ring (105) is likely to be easily terminated. The crack invasion into the semiconductor chip area (102) can be inhibited.

Meanwhile, as a modification of the third example, as described in the second example, the metal layers up to the metal layer lower than the uppermost metal layer of the wiring can also be used to form the crack prevention ring.

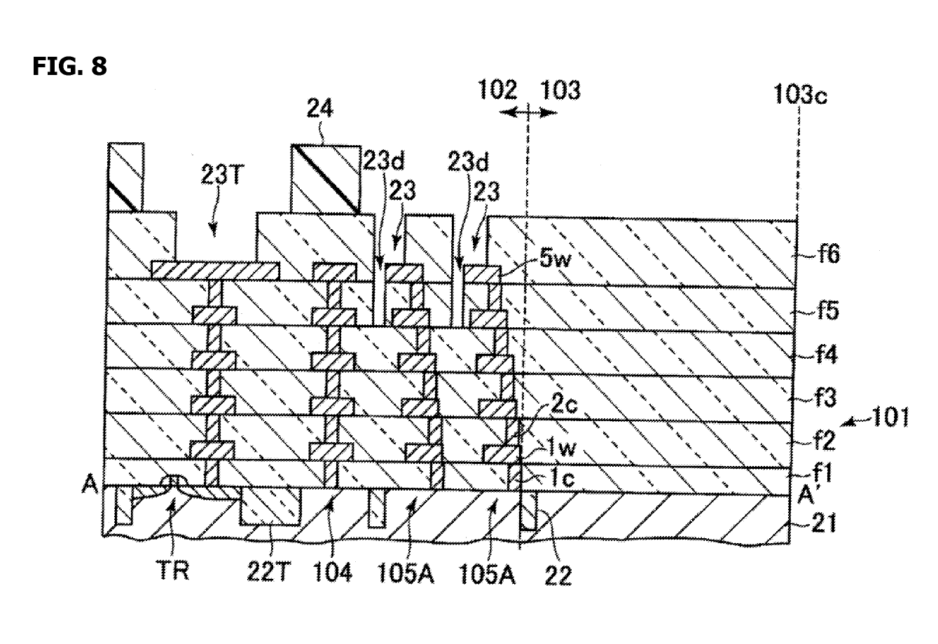

Next, in reference to FIG. 8, the crack prevention ring structure of a fourth example is explained. If multiple crack prevention ring structures are disposed, the capability to prevent cracking can be further enhanced. For example, as the fourth example, the crack prevention ring structure having the crack prevention ring (105A) and the crack prevention window (23) of the third example is doubled. Meanwhile, the multiple crack prevention rings are not required to be completely identical in structure.

So far in the first to fourth examples, a circuit production technique using aluminum wiring is used to form the respective crack prevention ring structures. Further, as explained in the following fifth to eleventh examples, the crack prevention ring structures can also be formed by using a circuit production technique using copper wiring.

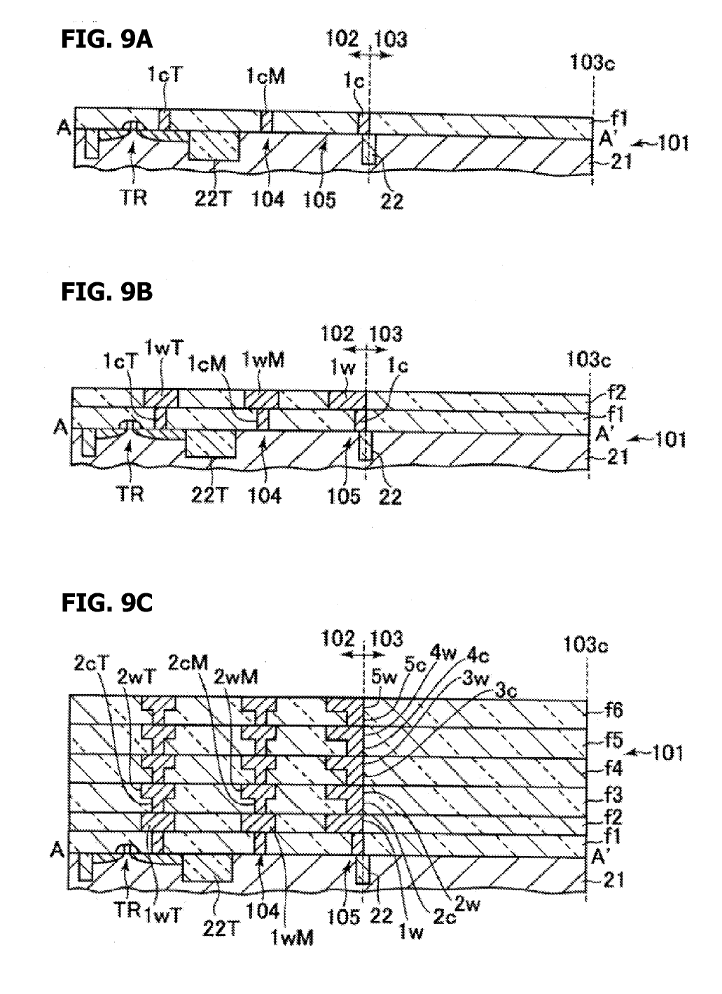

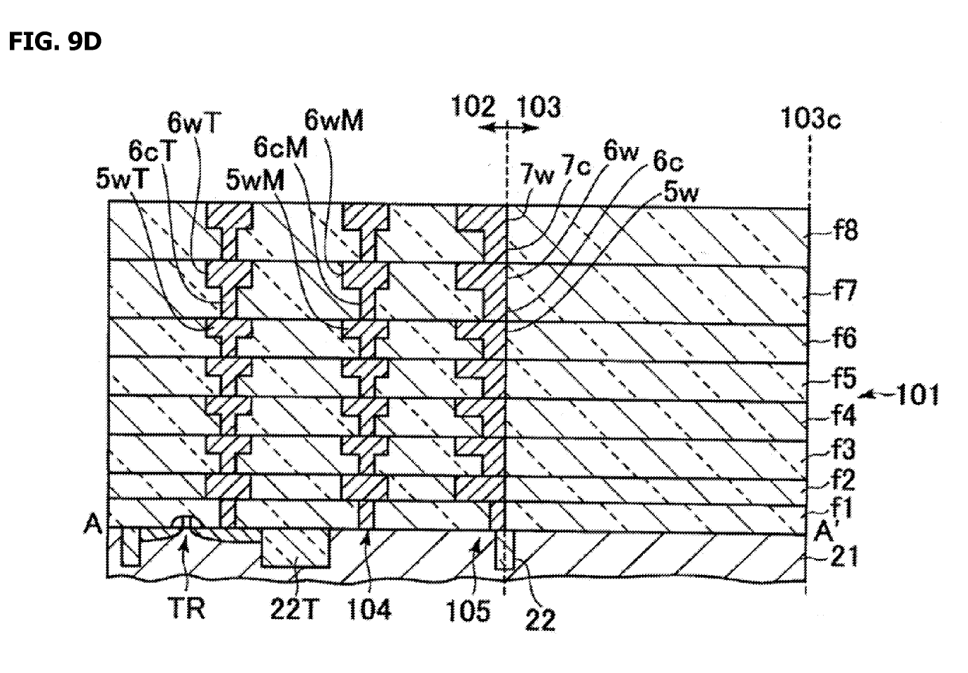

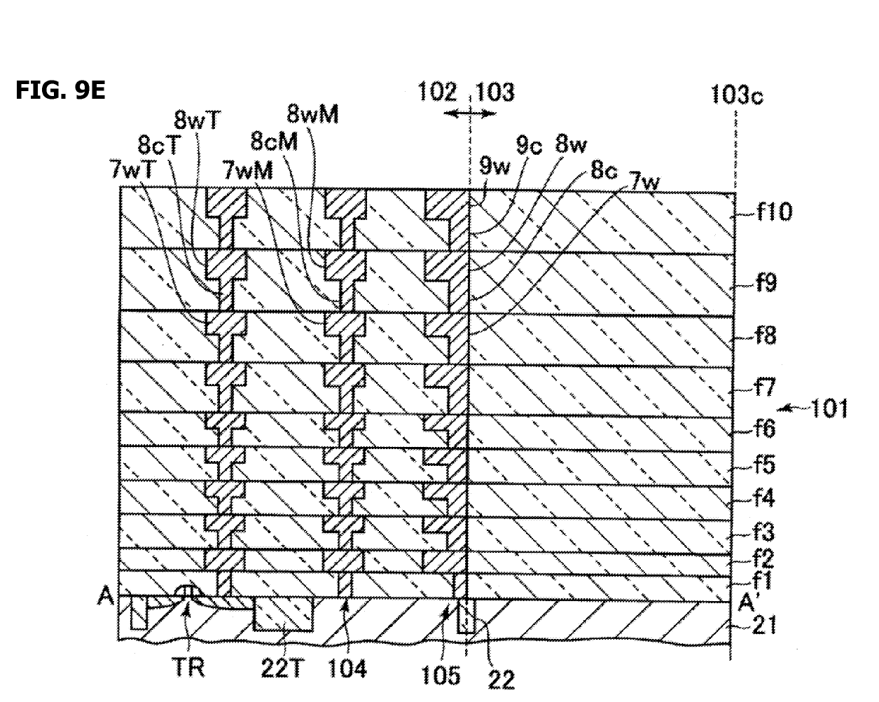

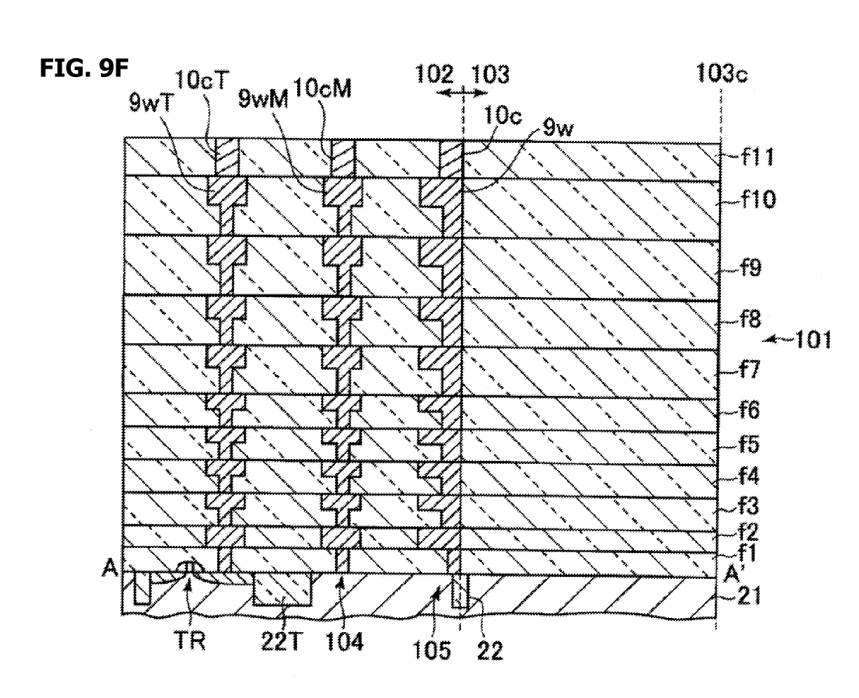

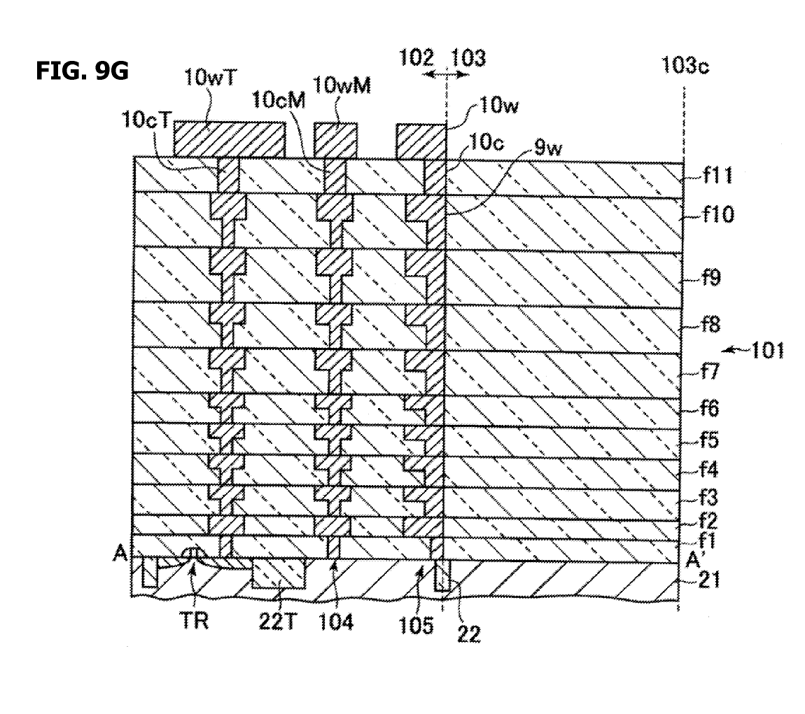

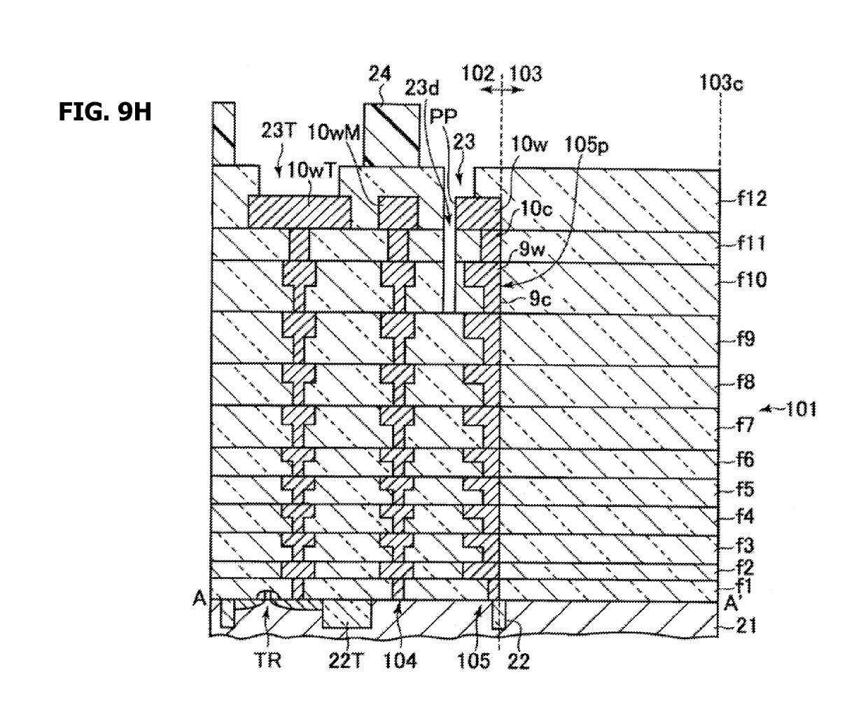

Next, in reference to FIGS. 9A to 9H, the crack prevention ring structure of the fifth example is explained. Meanwhile, to avoid the trouble of giving reference symbols, the reference symbols used in the explanation of the first example and others using aluminum wiring may also be used again in the fifth example and others using copper wiring.

The fifth example corresponds to the first example (see FIGS. 2A to 2G). That is, a crack prevention ring (105) having a smooth lateral surface (105p) is formed by using a multilayer copper wiring forming process. The general plan structure of the semiconductor wafer (101) provided with the crack prevention ring structure of the fifth example is the same as that of the first example (see FIG. 1). FIGS. 9A to 9H are schematic sectional views in the thickness direction illustrating the main production process of the semiconductor wafer (101) provided with the crack prevention ring structure of the fifth example. FIG. 9H illustrates the completed state of the semiconductor wafer (101).

Reference is made to FIG. 9A. In the silicon substrate (21), an element isolation insulation film (22T) for defining the active region of a transistor (TR) and a crack prevention insulation film (22) are formed simultaneously, for example, by STI. After forming the element isolation insulation film (22T) and the crack prevention insulation film (22), the transistor (TR) is formed on the silicon substrate (21). The transistor (TR) can be formed by using a publicly known technique as appropriate.

Then, a first interlayer insulation film (f1) is formed on the silicon substrate (21), while covering the transistor (TR). The first interlayer insulation film (f1) is formed, for example, as described below. On the silicon substrate (21), a silicon nitride film is deposited to have a thickness of approx. 30 nm by CVD, and on the silicon nitride film, a phosphosilicate glass (PSG) film is deposited to have a thickness of approx. 700 nm by CVD. Further, the upper surface of the PSG film is flattened by CMP, to form the first interlayer insulation film (f1). The thickness of the first interlayer insulation film (f1) is, for example, approx. 450 nm.

Then, in the first interlayer insulation film (f1), contact holes (1cT), (1cM) and (1c) for embedding wiring, a moisture-proof ring (104) and a first contact layer portion of a crack prevention ring (105) therein are formed by photolithography and etching. The widths of the first contact layer portion (1cM) of the moisture-proof ring (104) and the first contact layer portion (1c) of the crack prevention ring (105) are respectively, for example, approx. 0.1 m.

Then, on the first interlayer insulation film (f1), a Ti/TiN/W lamination film is formed to cover the inner surfaces of the contact holes (1cT), (1cM) and (1c). In the Ti/TiN/W lamination film, the Ti film has a thickness of, for example, approx. 10 nm and the TiN film has a thickness of, for example, approx. 10 nm. The respective films are deposited by sputtering. The W film has a thickness of, for example, approx. 200 nm and is deposited by CVD.

Then, the extra portions of the Ti/TiN/W lamination film are removed by CMP, to expose the upper layer of the first interlayer insulation film (f1) and to leave the first contact layer portions (1cT), (1cM) and (1c) in the contact holes (1cT), (1cM) and (1c) respectively.

Reference is made to FIG. 9B. The first wiring layer portions (1wT), (1wM) and (1w) in the second interlayer insulation film (f2) can be formed by the single damascene process. For example, specifically, they are formed as described below.

A silicon carbide film (with a thickness of approx. 30 nm), a silicon oxycarbide film (with a thickness of approx. 130 nm), a silicon oxide film (with a thickness of approx. 100 nm) using TEOS and a silicon nitride film (with a thickness of approx. 30 nm) are deposited. The silicon nitride film is coated with a resist (tri-level), and on the resist (tri-level), a silicon oxide film (with a thickness of approx. 100 nm) using TEOS is deposited. On the silicon oxide film, a resist pattern opened in the forms of the wiring grooves corresponding to the first wiring layer portion (1w), etc. is formed.

The resist pattern is used as a mask, to form a hard mask by the silicon oxide film using TEOS right under the resist pattern. Then, the resist pattern is removed. In this case, the tri-level resist in the openings is also simultaneously removed. The silicon oxide film using TEOS and the tri-level resist below it are used as masks, to etch the silicon nitride film, the silicon oxide film using TEOS and the silicon oxycarbide film. Meanwhile, the hard mask of the silicon oxide film using TEOS and the mask by the tri-level resist below it are removed by the etching.

Further, simultaneously with the etching to remove the silicon nitride film, the silicon carbide film is extracted to expose the underlying first contact layer portion (1c), etc. are exposed on the bottoms of the wiring groove (1w), etc. As the second interlayer insulation film (f2) having the wiring groove (1w), etc. formed therein, the laminated portion of the silicon carbide film, silicon oxycarbide film and silicon oxide film using TEOS remains.

Meanwhile, the recesses for embedding the wiring layer portions of the moisture-proof ring (104) and the crack prevention ring (105) are also called wiring grooves like the recess for embedding the wiring layer portion of the multilayer wiring therein. Further, the wiring grooves and the wiring layer portions embedded therein are indicated by the same reference symbols.

The width of the wiring groove portion (1wM), i.e., the width of the first wiring layer portion (1wM) of the moisture-proof ring (104) embedded therein is, for example, approx. 4 m. Further, the width of the wiring groove portion (1w), i.e., the width of the first wiring layer portion (1w) of the crack prevention ring (105) embedded therein is, for example, approx. 3 m. Meanwhile, the following explanation is made without distinguishing the widths of the wiring grooves from the widths of the wiring layer portions.

As in the first example, the first wiring layer portion (1w) of the crack prevention ring (105) (i.e., the wiring groove (1w)) is formed in such a manner that the end of it on the side of the scribe line area (103) may agree with the end the first contact layer portion (1c) on the side of the scribe line area (103).

Then, on the second interlayer insulation film (f2), for example, a Ta film is deposited as a barrier metal film by sputtering, while covering the inner surfaces of the first wiring grooves (1wT), (1wM) and (1w), and on the barrier metal film, a copper seed layer is deposited by sputtering. Further, on the seed layer, a copper film is formed by electroplating.

Then, the extra portions of the copper film, seed layer and barrier metal film are removed by CMP, to expose the upper surface of the second interlayer insulation film (f2), for thereby leaving the first wiring layer portions (1 wt), (1wM) and (1w) in the wiring grooves (1wT), (1wM) and (1w) respectively.

Reference is made to FIG. 9C. The second contact layer portions (2cT), (2cM) and (2c) and the second wiring layer portions (2wT), (2wM) and (2w) in the third interlayer insulation film (f3) can be formed by the well-known dual damascene process. For example, specifically, they can be formed as described below.

A silicon carbide film (with a thickness of approx. 60 nm), a silicon oxycarbide film (with a thickness of approx. 450 nm), a silicon oxide film (with a thickness of approx. 100 nm) using TEOS, and a silicon nitride film (with a thickness of approx. 30 nm) are deposited. On the silicon nitride film, a resist pattern opened in the forms of contact holes corresponding to the second contact layer portion (2c), etc. is formed. The resist pattern is used as a mask, to etch the silicon nitride film, the silicon oxide film using TEOS and the silicon oxycarbide film.

The resist pattern is removed, and a resist (tri-level) is formed by coating, then a silicon oxide film (with a thickness of approx. 140 nm) using TEOS being deposited. On the silicon oxide film, a resist pattern opened in the forms of wiring grooves corresponding to the second wiring layer portion (2w), etc. is formed. The resist pattern is used as a mask, to form a hard mask by the silicon oxide film using TEOS right under the resist pattern. Then, the resist pattern is removed. In this case, the tri-level resist in the openings is also simultaneously removed. The silicon oxide film using TEOS and the tri-level resist below it are used as masks, to etch the silicon nitride film, the silicon oxide film using TEOS and the silicon oxycarbide film partially in thickness, for thereby forming the wiring groove (2w), etc. Meanwhile, this etching removes the silicon oxide film using TEOS used as a hard mask and the tri-level resist below it used as a mask.

Further, simultaneously with the etching to remove the silicon nitride film, the silicon carbide film is extracted, to expose the underlying first wiring layer portion (1w), etc. at the bottoms of the contact hole (2c), etc. As the third interlayer insulation film (f3) having the second contact layer portion (2c), etc. and the second wiring layer portion (2w), etc. formed therein, the laminated portion of the silicon carbide film, the silicon oxycarbide film and the silicon film using TEOS remains.

The second contact layer portion (2c) and the second wiring layer portion (2w) of the crack prevention ring (105) are formed in such a manner that the ends of the layers may agree with the end of the first wiring layer (1w) on the side of the scribe line area (103). That is, in the disposal corresponding to this configuration, the contact hole (2c) and the wiring groove (2w) are formed. Further, as in the first example, the ends of the upper contact layers and wiring layers on the side of the script lane area (103) are made to agree likewise for thereby forming a smooth lateral surface on the side of the scribe line area (103).

For example, the depths of the wiring grooves (2wT), (2wM) and (2w) from the upper surface of the third interlayer insulation film (f3) are about one half of the thickness of the silicon oxycarbide film and the silicon oxide film using TEOS, being approx. 275 nm. On the contrary, the heights of the contact holes (2cT), (2cM) and (2c) are, for example, approx. 335 nm.

The widths of the second contact layer portion (2cM) of the moisture-proof ring (104) and the second contact layer portion (2c) of the crack prevention ring (105) are respectively, for example, approx. 0.13 m. Further, for example, the width of the second wiring layer portion (2wM) of the moisture-proof ring (104) is approx. 4 m like the first wiring layer portion (1wM). For example, the width of the second wiring layer portion (2w) of the crack prevention ring (105) is approx. 3 m like the first wiring layer portion (1w).

The widths of the wiring layer portions of the moisture-proof ring (104) and the crack prevention ring (105) remain the same also in the third and higher wiring layers formed thereafter. However, the uppermost wiring layer portion (10w) of the crack prevention ring (105) is formed to be rather wider owing to the projected portion as described later.

Meanwhile, a technique of forming contact holes at first and forming wiring grooves later is described as an example, but as required, a technique of forming wiring grooves at first and forming contact holes later can also be applied.

Then, on the third interlayer insulation film (f3), a barrier metal, for example, a Ta film is deposited by sputtering to cover the inner surfaces of the contact holes (2cT), (2cM) and (2c) and the inner surfaces of the wiring grooves (2wT), (2wM) and (2w), and on the barrier metal film, a copper seed layer is deposited by sputtering. Further, on the seed layer, a copper film is formed by electroplating.

Then, the extra portions of the copper film, the seed layer and the barrier metal film are removed by CMP, to expose the upper surface of the third interlayer insulation film (f3), for thereby leaving the second contact layer portions (2cT), (2cM) and (2c) in the contact holes (2cT), (2cM) and (2c), and the second wiring layer portions (2wT), (2wM) and (2w) in the wring grooves (2wT), (2wM) and (2w).

Meanwhile, in the dual damascene process, a contact layer and the wiring layer on it are formed simultaneously, but to facilitate explanation, as members forming the crack prevention ring, the contact layer and the wiring layer are treated as different metal layers. For example, for the contact layer and the wiring layer simultaneously formed by dual damascene, an expression like “a wiring layer is laminated on a contact layer” may be used as the case may be.

Subsequently, the same process as that for forming the second contact layer and the second wiring layer on the third interlayer insulation film (f3) is repeated to form the third contact layer portion (3c), etc. and the third wiring layer portion (3w), etc. up to the fifth contact layer portion (5c), etc. and the fifth wiring layer portion (5w), etc. on the fourth to sixth interlayer insulation films (f4) to (f6) respectively.

Furthermore, the sixth contact layer portion (6c), etc. and the sixth wiring layer portion (6w), etc. up to the ninth contact layer portion (9c), etc. and the ninth wiring layer portion (9w), etc. are formed on the upper interlayer insulation films (f7) to (f10) respectively likewise by the dual damascene process (as explained in reference to FIGS. 9D and 9E). However, the widths and heights of the contact layer portions and the heights of the wiring layer portions are different from those of the lower layer portions.

Reference is made to FIG. 9D. For example, the sixth contact layer portions (6cT), (6cM) and (6c) and the sixth wiring layer portions (6wT), (6wM) and (6w) in the seventh interlayer insulation film (f7) are formed as described below.

A silicon carbide film (with a thickness of approx. 70 nm), a silicon oxycarbide film (with a thickness of approx. 920 nm), a silicon oxide film (with a thickness of approx. 30 nm) using TEOS, a silicon nitride film (with a thickness of approx. 50 nm) and a silicon oxide film (with a thickness of approx. 10 nm) are deposited. On the silicon oxide film, a resist pattern opened in the forms of the contact holes corresponding to the sixth contact layer portion (6c), etc. is formed. The resist pattern is used as a mask, to etch the silicon oxide film, the silicon nitride film, the silicon oxide film using TEOS and the silicon oxycarbide.

The resist patter is removed, and then a resist (tri-level) is formed by coating. Further the resist (tri-level) is etched back till the underlying silicon oxide film is exposed, and subsequently a resist pattern opened in the forms of the wiring grooves corresponding to the sixth wiring layer portion (6w), etc. is formed. The resist pattern is used as a mask, to etch the silicon oxide film, the silicon nitride film the silicon oxide film using TEOS and the silicon oxycarbide film partially in thickness, to form the wiring groove (6w), etc.

Subsequently the resist pattern is removed, and further simultaneously with the etching to remove the silicon oxide film and the silicon nitride film, the silicon carbide film is extracted to expose the underlying fifth wiring layer portion (5w), etc. at the bottoms of the contact hole (6c), etc. As the seventh interlayer insulation film (f7) having the sixth contact layer portion (6c), etc. and the sixth wiring layer (6w), etc. formed therein, the laminated portion of the silicon carbide film, the silicon oxycarbide film and the silicon oxide film using TEOS remains.

For example, the depths of the wiring grooves (6wT), (6wM) and (6w) from the upper surface of the seventh interlayer insulation film (f7) are about one half of the thickness of the silicon oxycarbide film and the silicon oxide film using TEOS, being approx. 0.5 m. In correspondence to the depths, the heights of the contact holes (6cT), (6cM) and (6c) are, for example, approx. 0.5 m. The widths of the six contact layer portion (6cM) of the moisture-proof ring (104) and the sixth contact layer portion (6c) of the crack prevention ring (105) are respectively, for example, approx. 0.24 m.

Further, sixth contact layer portions (6cT), (6cM) and (6c) and sixth wiring layer portions (6wT), (6wM) and (6w) are formed in the contact holes and in the wiring grooves of the seventh interlayer insulation film (f7) by copper plating and CMP.

Then, the same process as that for forming the sixth contact layer portions (6cT), (6cM) and (6c) and the sixth wiring layer portions (6wT), (6wM) and (6w) in the seventh interlayer insulation film (f7) is repeated to form seventh contact layer portion (7c), etc. and seventh wiring layer portion (7w), etc. in an eighth interlayer insulation film (f8).

Reference is made to FIG. 9E. For example, eighth contact layer portions (8cT), (8cM) and (8c) and eighth wiring layer portions (8wT), (8wM) and (8w) are formed in a ninth interlayer insulation film (f9) as described below.

A silicon carbide film (with a thickness of approx. 70 nm), a silicon oxide film (with a thickness of approx. 1500 nm), a silicon oxide film (with a thickness of approx. 30 nm) using TEOS and a silicon nitride film (with a thickness of approx. 50 nm) are deposited. On the silicon nitride film, a resist pattern opened in the forms of the contact holes corresponding to the eighth contact layer portion (8c), etc. is formed. The resist pattern is used as a mask, to etch the silicon nitride film, the silicon oxide film using TEOS and the silicon oxide film below it.

The resist pattern is removed, and subsequently a resist (tri-level) is formed by coating. Further, the resist (tri-level) is etched back till the silicon nitride film below it is exposed, and then a resist pattern opened in the forms of the wiring grooves corresponding to the eighth wiring layer portion (8w), etc. is formed. The resist pattern is used as a mask, to etch the silicon nitride film, the silicon oxide film using TEOS and the silicon oxide film below it partially in thickness, to form the wiring groove (8w), etc.

Subsequently the resist pattern is removed, and further, simultaneously with the etching to remove the silicon nitride film, the silicon carbide film is extracted to expose the seventh wiring layer portion (7w), etc. in the bottoms of the contact hole (8c), etc. As the ninth interlayer insulation film (f9) having the eighth contact layer portion (8c), etc. and the eighth wiring layer portion (8w), etc., the laminated portion of the silicon carbide film, the silicon oxide film and the silicon oxide film using TEOS remains.

For example, the depths of the wiring grooves (8wT), (8wM) and (8w) from the upper surface of the ninth interlayer insulation film (f9) are about one half of the thickness of the silicon carbide film and the silicon oxide film, being approx. 0.8 m. In correspondence to the depths, the heights of the contact holes (8cT), (8cM) and (8c) are, for example, approx. 0.8 m. The widths of the eighth contact layer portion (8cM) of the moisture-proof ring (104) and the eighth contact layer portion (8c) of the crack prevention ring (105) are respectively, for example, approx. 0.38 m.

Further, the eighth contact layer portions (8cT), (8cM) and (8c) and eighth wiring layer portions (8wT), (8wM) and (8w) are formed in the contact holes and in the wiring grooves of the ninth interlayer insulation film (f9) by copper plating and CMP.

Then, the same process as that for forming the eighth contact layer portions (8cT), (8cM) and (8c) and the eighth wiring layer portions (8wT), (8wM) and (8w) in the ninth interlayer insulation film (f9) is repeated to form the ninth contact layer portion (9c), etc. and the ninth wiring layer portion (9w), etc. in a tenth interlayer insulation film (f10).

Reference is made to FIG. 9F. At first, an eleventh interlayer insulation film (f11) is formed on the tenth interlayer insulation film (f10), while covering the ninth wiring layer portions (9wT), (9wM) and (9w). The eleventh interlayer insulation film (f11) is formed, for example, as described below. A silicon carbide film is deposited to have a thickness of approx. 70 nm on the tenth interlayer insulation film (f10) by CVD, and on the silicon carbide film, a silicon oxide film is deposited to have a thickness of approx. 1200 nm by CVD. Then, the upper surface of the silicon oxide film is polished by CMP by approx. 300 nm to 400 nm, to be flattened. By the operation described here, the eleventh interlayer insulation film (f11) with a thickness of, for example, approx. 1 m is formed.

Then, in the eleventh interlayer insulation film (f11), contact holes (10cT), (10cM) and (10c) for embedding the contact layer portions of the wiring, the moisture-proof ring (104) and the crack prevention ring (105) therein are formed by photolithography and etching. The widths of the tenth contact layer portion (10cM) of the moisture-proof ring (104) and the tenth contact layer portion (10c) of the crack prevention ring (105) are respectively, for example, approx. 48 m.

Then, the tenth contact layer portions (10cT), (10cM) and (10c) are formed in the contact holes (10cT), (10cM) and (10c) by the deposition of a barrier metal film such as a Ti film and a W film and CMP.

Reference is made to FIG. 9G. The aluminum wiring material is deposited to have a thickness of, for example, approx. 1100 nm, and is patterned to form the tenth wiring layer portions (10wT), (10wM) and (10w) of the wiring, the moisture-proof ring (104) and the crack prevention ring (105) as the uppermost metal layer.

The tenth wiring layer portion (10w) of the crack prevention ring (105) is disposed in such a manner that the lateral face of the tenth wiring layer portion (10w) on the side of the semiconductor chip area (102) may be more on the side of the semiconductor chip area (102) than the lateral faces on the side of the semiconductor chip area (102), of the ninth wiring layer portion (9w), etc. formed of copper and disposed below the tenth wiring layer portion. That is, the tenth wiring layer (10w) is formed to project like a roof edge toward the side of the semiconductor chip area (102) compared with the ninth wiring layer portion (9w), etc. disposed below the tenth wiring layer portion.

Reference is made to FIG. 9H. A cover insulation film (f12) is formed on the eleventh interlayer insulation film (f11), while covering the tenth wiring layer portions (10wT), (10wM) and (10w). For example, the cover insulation film (f12) is formed by depositing a silicon oxide film with a thickness of approx. 1400 nm on the eleventh interlayer insulation film (f11) by CVD and depositing a silicon nitride film with a thickness of approx. 500 nm on the silicon oxide film by CVD.

Then, a contact window (23T) and a crack prevention window (23) are formed in the cover insulation film (f12) by photolithography and etching. Further, as required, on the cover insulation film (f12), an insulation film (24) of a polyimide or the like is formed.

The crack prevention window (23) of the fifth example exposes the wiring layer portion (10w) in the portion where it is formed right above the wiring layer portion (10w), and in the dug portion (23d) outside the wiring layer portion (10w) (on the side of the semiconductor chip area (102)), the bottom reaches the halfway height of the crack prevention ring (105). In the example illustrated in FIG. 9H, the bottom of the dug portion (23d) reaches the upper surface of the interlayer insulation film (f9). The overall width of the crack prevention window (23) is, for example, approx. 1 m to approx. 3 m. The width of the portion where the crack prevention window (23) is formed on the uppermost metal layer portion (10w) is, for example, approx. 0.5 m, and the width of the dug portion (23d) is, for example, approx. 1.0 m.

In the fifth example, the uppermost metal layer portion (10w) formed of aluminum in the crack prevention ring (105) is formed to project like a roof edge toward the side of the semiconductor chip area (102) compared with the metal layer portion (9w), etc. formed of copper below the uppermost metal layer portion. With this configuration, the metal layer portion (10w) can work as a mask during etching, and the dug portion (23d) can be formed without allowing the underlying metal layer portion (9w), etc. to be exposed inside.

If the lateral face of the uppermost metal layer portion (10w) on the side of the semiconductor chip area (102) is flush with the lateral faces of the metal layer portion (9w), etc. below the uppermost metal layer portion for example as described in the first example, the metal layer portion (9w), etc. formed of copper are exposed on the inner surface of the dug portion (23d). If the chamber used for etching to form the crack prevention window (23) can be used also for processing copper layers, the exposure of copper layers does not pose any problem. However, the copper contamination in the chamber may be undesirable as the case may be. In such a case, it is preferred to form a crack prevention window (23) with a structure that does not allow the copper layers to be exposed in the dug portion (23d) as in the fifth example.

If the projection length of the wiring layer portion (10w) toward the side of the semiconductor chip area (102) is designed to be large to some extent, the roof edge-like portion (PP) can be positively formed in the completed product. An example of estimating the projection length to be set for the lateral face of the wiring layer portion (10w) on the side of the semiconductor chip area (102) compared with the lateral face of the wiring layer portion (9w) on the side of the semiconductor chip area is explained below.

In the fifth example, within the crack prevention window (23), the eleventh interlayer insulation film (f11) and the tenth interlayer insulation film (f10) below the tenth wiring layer portion (10w) are etched. That is, it is desired that the lateral faces of the tenth contact layer portion (10c), the ninth wiring layer portion (9w) and the ninth contact layer portion (9c) are not exposed.

Assuming 90 nm technology, if the maximum value of the positional shift allowance of the tenth wiring layer portion (10w) relative to the underlying contact layer portion (10c) is 0.3 m, the maximum value of the positional shift allowance of the tenth contact layer portion (10c) relative to the underlying wiring layer portion (9w) is 0.1 m, and the maximum value of the positional shift allowance of the ninth wiring layer portion (9w) relative to the underlying contact layer portion (9c) is 0.065 m, then the maximum positional shift dispersion (allowable positional shift amount) of the uppermost wiring layer portion (10w) relative to the contact layer portion of two layers below is obtained as the square root of the sum obtained by adding the respective squares of 0.3 m, 0.1 m and 0.065 m and is estimated to be 0.33 m.

On the other hand, the line width dispersion of the tenth wiring layer portion (10w) or the ninth wiring layer portion (9w) is estimated to be 0.15 m respectively at the maximum (in the case where the dispersion allowance is 10% of the wiring layer width and where the value on one side is taken into account). The line width dispersion of the ninth contact layer portion (9c) is considered to be within the line width dispersion of the wiring layer portion (9w or 10w), since the ninth contact layer portion (9c) is thinner than the wiring layer portion (9w or 10w). Consequently, the maximum line width dispersion is obtained as the square root of the sum of the respective squares of 0.15 m and 0.15 m and is estimated to be 0.21 m.

Therefore, for example, in view of reliably forming the roof edge-like portion (PP), 0.4 m obtained as the square root of the sum of the respective squares of the alignment dispersion 0.33 m and the line width dispersion 0.21 m can be set as the projection length.

The crack prevention ring (105) of the fifth example is also inhibited from being broken when a crack propagates, owing to the smooth lateral surface (105p) on the side of the scribe line area (103). Further, the crack prevention window (23) having the dug portion (23d) terminates the crack on the uppermost metal layer of the crack prevention ring (105), and is likely to terminate the crack penetrating through the crack prevention ring (105). The crack invasion into the semiconductor chip area (102) can be inhibited.

As described above, the semiconductor wafer (101) provided with the crack prevention ring structure of the fifth example is formed. Meanwhile, the number of the layers of the multilayer wiring, i.e., the number of the metal layers forming the crack prevention ring can be changed as appropriate in response to the type of the semiconductor chips.

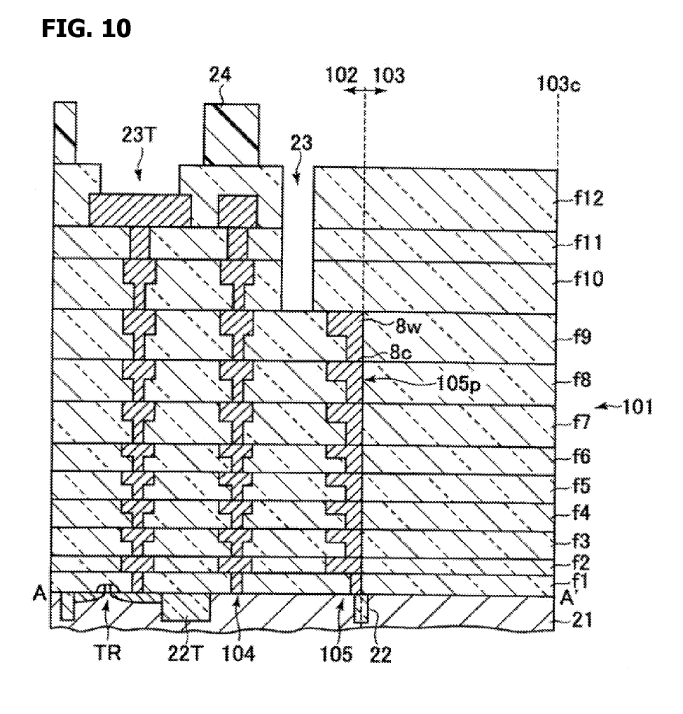

Next, in reference to FIG. 10, the crack prevention ring structure of a sixth example is explained. The sixth example corresponds to the second example (see FIG. 6), and the crack prevention ring (105) is formed using the metal layers lower than the uppermost metal layer of the wiring. Specifically, the copper wiring layers up to (8w) are used.

However, in the sixth example, the crack prevention window (23) is formed without exposing the crack prevention ring (105). That is, in the structure, the copper layers are not exposed in the crack prevention window (23).

Accordingly the crack prevention window (23) is disposed apart from the crack prevention ring (105) toward the side of the semiconductor chip area (102). It is preferred that the depth of the crack prevention window (23) is not higher than the upper surface of the uppermost metal layer of the crack prevention ring (105). The depth of the crack prevention window (23) is flush with the upper surface of the uppermost metal layer portion (8w) of the crack prevention ring (105) in the example illustrated in FIG. 10, but can also be deeper. The width of the crack prevention window (23) is, for example, approx. 1 m.

In the crack prevention ring structure of the sixth example, if the crack propagating upward along the lateral surface (105p) of the crack prevention ring (105) on the side of the scribe line area (103) reaches the uppermost metal layer portion (8w) of the crack prevention ring (105), the crack is guided along the interface between the upper surface of the metal layer portion (8w) and the interlayer insulation film (f10) toward the side of the semiconductor chip area (102), to reach the crack prevention window (23). Thus, the crack can be terminated.

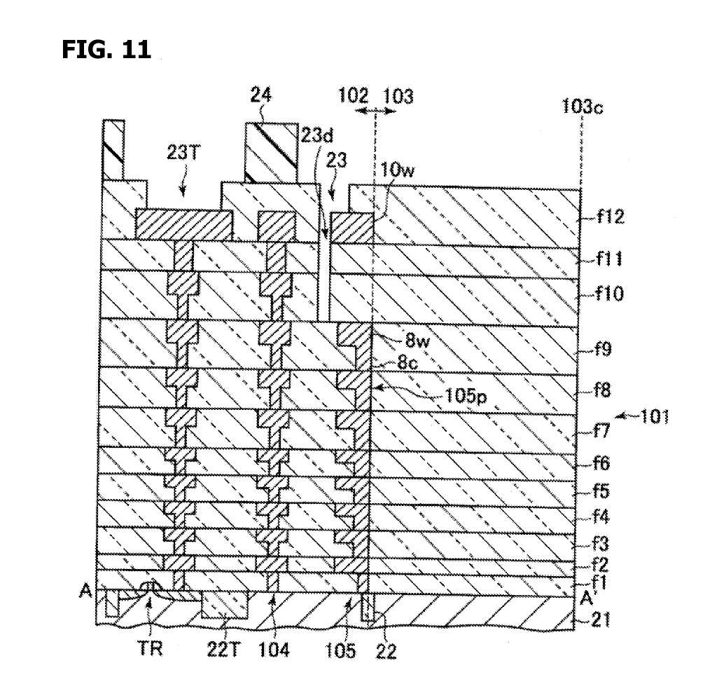

Next, in reference to FIG. 11, the crack prevention ring structure of a seventh example is explained. The crack prevention ring (105) of the seventh example can be considered to have a structure in which an aluminum wiring layer portion (10w) at the same level as the uppermost metal layer portion (10wT) of the wiring is added as an auxiliary metal ring to the crack prevention ring (105) of the sixth example. Meanwhile, the structure can also be considered as a structure in which the contact layer portion (10c), the wiring layer portion (9w) and the contact layer portion (9c) are removed from the crack prevention ring (105) of the fifth example.

The crack prevention window (23) of the seventh example exposes the wiring layer portion (10w) in the portion where it is formed right above the wiring layer portion (10w) like the crack prevention window (23) of the fifth example, and the dug portion (23d) outside the wiring layer portion (10w) (on the side of the semiconductor chip area (102)) is formed deeper than the wiring layer portion (10w). The depth of the dug portion (23d) reaches the height of the upper surface of the interlayer insulation film (f9), i.e., the height of the upper surface of the uppermost wiring layer portion (8w) formed of copper of the crack prevention ring (105) in the example illustrated in FIG. 11. The dug portion (23d) can also be further deeper.

The wiring layer portion (10w) formed of aluminum projects like a roof edge toward the side of the semiconductor chip area (102) compared with the wiring layer portion (8w), etc. formed of copper. With this configuration, below the dug portion (23d), the metal layers forming the crack prevention ring (105) are not disposed, and it does not happen that the copper layers are exposed inside the dug portion (23d).

In the sixth example, in order to avoid that the copper layers are exposed in the crack prevention window (23), the lateral surface of the crack prevention window (23) on the side of the scribe line area (203) is apart from the lateral surface of the crack prevention ring (105) on the side of the semiconductor chip area (102) toward the side of the semiconductor chip area (102).

In the seventh example, when the dug portion (23d) is formed, the aluminum wiring layer portion (10w) (auxiliary metal ring) functions as a mask with a roof edge portion. Therefore, even if the lateral surface of the crack prevention window (23) on the side of the scribe line area (103) is disposed to overlap the crack prevention ring (105) on the plan view, it can be avoided that the copper layers of the crack prevention ring (105) are exposed in the dug portion (23d).

With this configuration, in the seventh example, the width from the lateral surface of the crack prevention window (23) on the side of the semiconductor chip area (102) to the lateral surface of the crack prevention ring (105) on the side of the scribe line area (103) (i.e., the width required for disposing the crack prevention ring structure) can be more easily narrowed than in the sixth example.

In the crack prevention ring structure of the seventh example, if the crack propagating upward along the lateral surface (105p) of the crack prevention ring (105) on the side of the scribe line area (103) reaches the uppermost metal layer portion (8w) of the laminated portion of the crack prevention ring (105), the crack is guided along the interface between the upper surface of the metal layer portion (8w) and the interlayer insulation film (f10) toward the side of the semiconductor chip area (102), to reach the crack prevention window (23). Thus, the crack can be terminated.

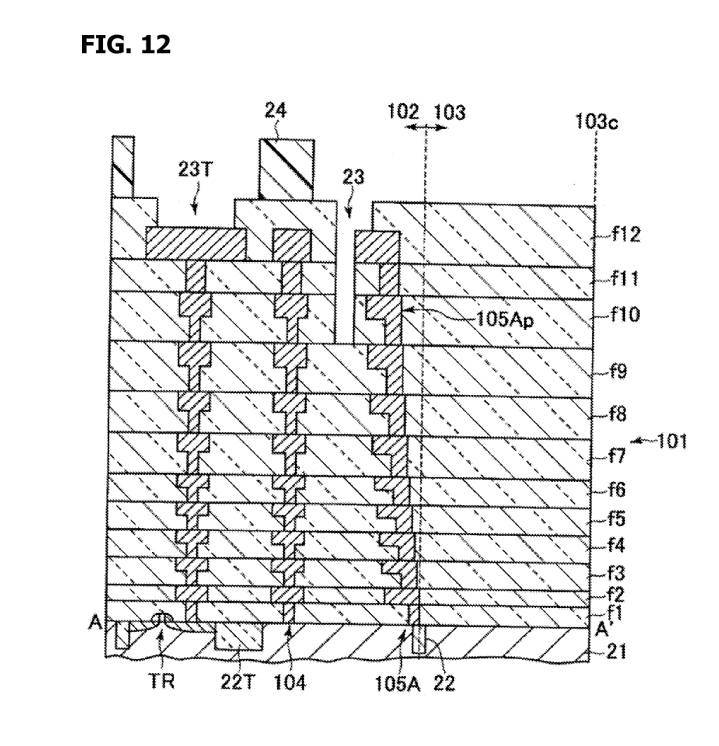

Next, in reference to FIG. 12, the crack prevention ring structure of an eighth example is explained. The eighth example corresponds to the third example (see FIG. 7). That is, the lateral surface (105Ap) of the crack prevention ring (105A) inclines in such a manner that the upper portion of the crack prevention ring (105A) becomes closer to the side of the semiconductor chip area (102). The crack prevention ring (105A) of the eighth example can be produced by partially changing the method for producing the crack prevention ring (105) of the fifth example.

However, the crack prevention ring (105A) of the eighth example contains the metal layers formed by the dual damascene process in the intermediate height portion. In the formation by the dual damascene process, the end of the wiring layer formed on the contact layer on the side of the scribe line area (103) is not disposed more on the side of the semiconductor chip area (102) than the end of the contact layer on the side of the scribe line area (103).

Therefore, in the case where no roof edge portion is formed, it is most preferred that the ends of the contact layer and the wiring layer simultaneously formed by the dual damascene process on the side of the scribe line area (103) are flush with each other.

Unlike the third example, in the eighth example, the ends of the contact layer and the wiring layer formed simultaneously by the dual damascene process on the side of the scribe line area (103) are flush with each other. Further, in the case where a contact layer is formed by the next dual damascene process on the wiring layer formed by the previous dual damascene process, the contact layer is disposed at a position shifted toward the side of the semiconductor chip area (102). For example, the shifting width is not larger than one half of the width of the contact layer formed on the wiring layer.

In the portion where a process of forming a contact layer or wiring layer by patterning a single layer, a wiring layer can be shifted on the underlying contact layer, to form an inclined lateral surface (105Ap) as in the third example. Meanwhile, also in the portion where such a process is employed, the end of the contact layer and the end of the wiring layer formed on it on the side of the scribe line area (103) can also be made to be flush with each other.

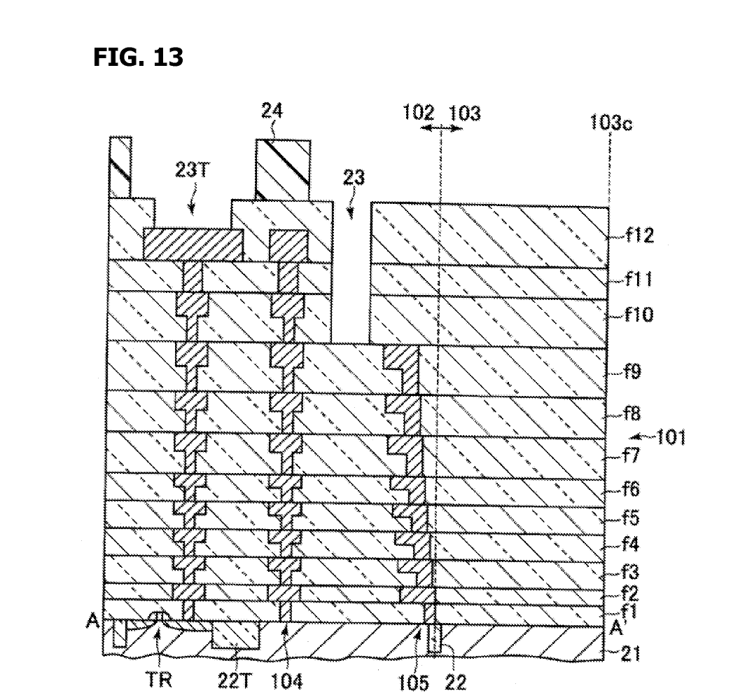

Next, in reference to FIG. 13, the crack prevention ring structure as a ninth example is explained. The ninth example has a structure in which the crack prevention ring of the sixth example (see FIG. 10) is replaced by an inclined crack prevention ring as employed in the eighth example.

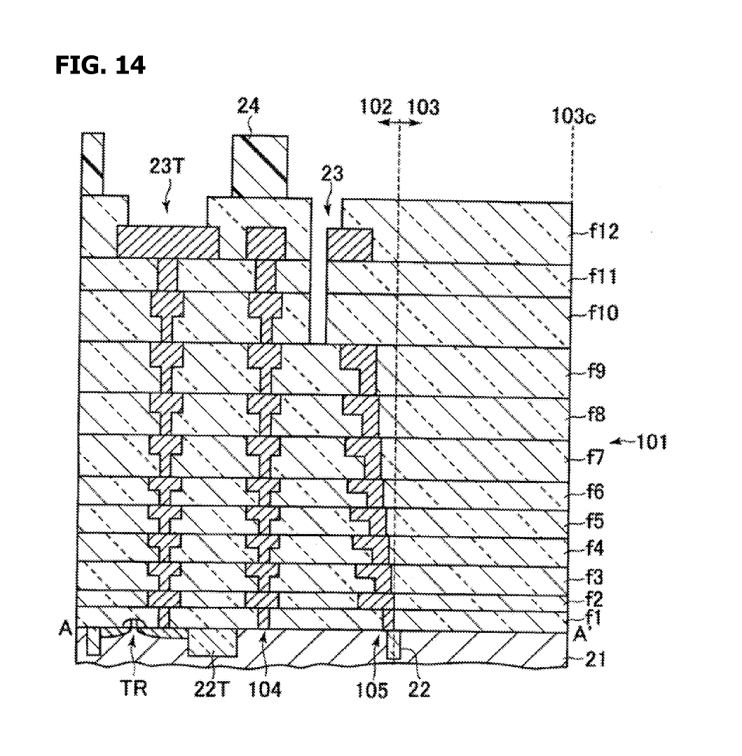

Next, in reference to FIG. 14, the crack prevention ring structure as a tenth example is explained. The tenth example has a structure in which the crack prevention ring of the seventh example (see FIG. 11) is replaced by an inclined crack prevention ring as employed in the eighth example.

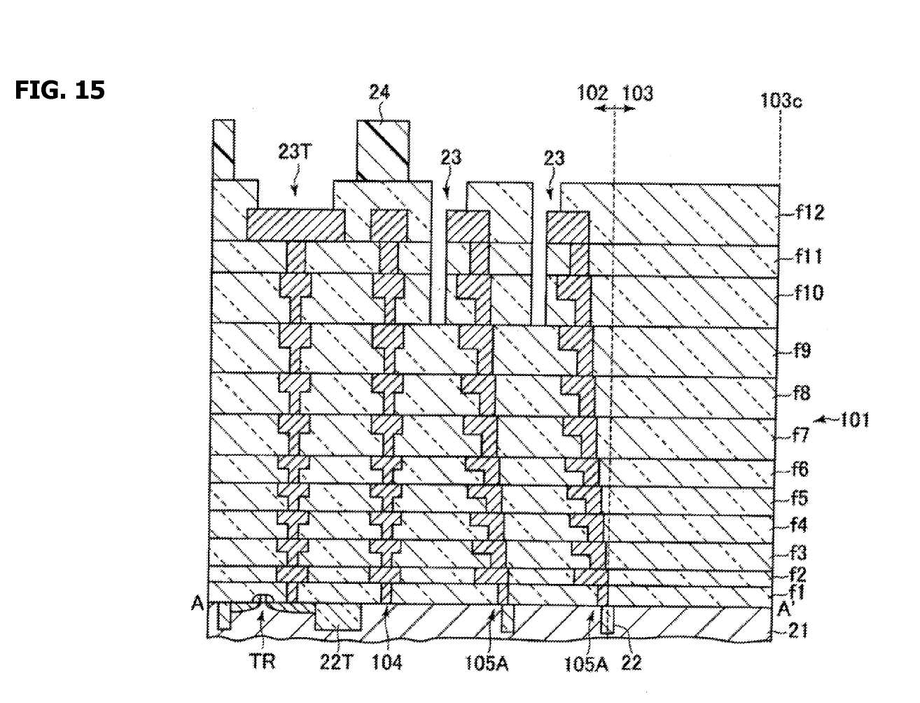

Next, in reference to FIG. 15, the crack prevention ring structure as an eleventh example is explained. In the eleventh example, multiple crack prevention ring structures are disposed as in the fourth example (see FIG. 8). For example, as illustrated in FIG. 15, the crack prevention ring structure having the crack prevention ring (105A) and the crack prevention window (23) of the eighth example is doubled. Meanwhile, the multiple crack prevention rings are not required to be completely identical in structure.

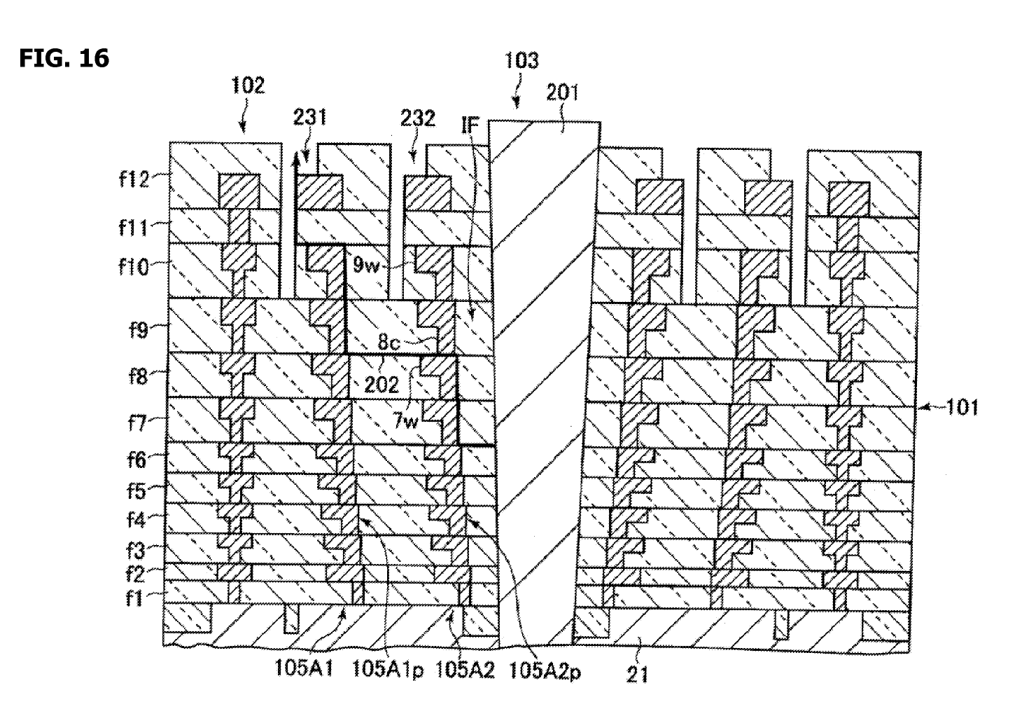

In reference to FIG. 16, the function of the crack prevention ring structure of the eleventh example is explained. FIG. 16 is a schematic sectional view in the thickness direction illustrating the state where the semiconductor wafer (101) provided with the crack prevention ring structure of the eleventh example is cut by a dicing saw (201).

In the example illustrated in FIG. 16, the crack prevention ring structure having the crack prevention ring (105A) and the crack prevention window (23) of the tenth example is doubled. In this example, the crack prevention rings (105A) are formed by using up to the wiring layer portions (9w) in the laminated portions, and the crack prevention windows (23) are formed to a depth corresponding to the upper surface of the interlayer insulation film (f9). Meanwhile, the depths of the crack prevention windows (23) can be adjusted as required. The crack prevention ring structures on the side of the semiconductor chip area (102) and on the side of the scribe line area (103) are distinguished by attaching reference symbols “1” and “2”.

In the example illustrated in FIG. 16, the crack (202) that is generated near a dicing saw (201) and propagates along the interface between interlayer insulation films (f6) and (f7) in the in-plane direction reaches the lateral surface (105A2p) of a crack prevention ring (105A2) and propagates upward along the lateral surface (105A2p).

The crack (202) penetrates the crack prevention ring (105A2) at the interface between a wiring layer portion (7w) and a contact layer portion (8c) (the interface between interlayer insulation films (f8) and (f9). The crack prevention window (232) formed above the crack prevention ring (105A2) does not reach the depth corresponding to the interface between interlayer insulation films (f8) and (f9), and the crack (202) penetrating through the crack prevention ring (105A2) propagates toward the side of the semiconductor chip area (102), to reach the lateral surface (105A1p) of a crack prevention ring (105A1).

The crack (202) that reaches the lateral surface (105A1p) propagates upward along the lateral surface (105A1p), to reach the uppermost metal layer portion (9w) in the laminate portion of the crack prevention ring (105), being guided along the interface between the upper surface of the metal layer portion (9w) and an interlayer insulation film (f11) toward the side of the semiconductor chip area (102), then reaching the crack prevention window (231), to be terminated. Thus, if a crack prevention ring structure is disposed, the capability of preventing a crack can be further enhanced.

As explained above, if any of the crack prevention ring structures of the first to eleventh examples is employed, a crack generated when the semiconductor wafer is sawn can be inhibited from propagating into the semiconductor chip area. In the metal ring used as a crack prevention ring, it is preferred that each upper metal layer overlaps the underlying metal layer in such a manner that the lateral face of the each upper metal layer on the outside of the semiconductor chip area and the lateral face of the underlying metal layer on the outside of the semiconductor chip area may be flush with each other or that the lateral face of the each upper metal layer on the outside of the semiconductor chip area may be positioned more inside the semiconductor chip area than the end of the underlying metal layer on the outside of the semiconductor chip area. With this configuration, the breaking of the crack prevention ring caused by the crack propagation along the lateral surface of the crack prevention ring can be inhibited.

It is preferred that the crack prevention window is disposed more inside the semiconductor chip area than the crack prevention ring and keeps the bottom thereof not higher than the upper surface of the uppermost metal layer of the crack prevention ring. For example, the crack prevention window (23) of the first example (see FIG. 2G) exposes the uppermost metal layer portion (5w) of the crack prevention ring (105), and the depth of the portion disposed inside the semiconductor chip area (i.e., the dug portion (23d)) is not higher than the lower surface of the uppermost metal layer portion (5w). Further, for example, the crack prevention window (23) of the sixth example (see FIG. 10) does not expose the uppermost metal layer portion (8w) of the crack prevention ring (105), and the depth of the portion disposed inside the semiconductor chip area (i.e., the whole of the crack prevention window (23)) is not higher than the upper surface of the uppermost metal layer portion (8w).

The crack prevention ring remains in the edge portion of each semiconductor chip after separation. In the case where there is a portion where an interlayer insulation film in the scribe line area is delaminated by a crack, the lateral surface of the crack prevention ring is exposed on the end surface of the semiconductor chip.

Meanwhile, examples in which a moisture-proof ring is formed more inside than a crack prevention ring have been explained, but if the crack prevention ring can also act as a moisture-proof ring, it can also be considered to save the moisture-proof ring formed more inside than the crack prevention ring.

Meanwhile, in the case where the moisture-proof ring is formed in addition to the crack prevention ring, a moisture-proof ring with a publicly known other structure can also be formed, as appropriate, without being limited to the moisture-proof ring of the structure explained in the examples.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
a semiconductor substrate;
a semiconductor element formed on the semiconductor substrate;
a first metal ring surrounding the semiconductor element;
an insulation film formed to cover the semiconductor element and having the first metal ring disposed therein; and
a groove formed in the insulation film;
wherein:
the first metal ring is formed by laminating multiple metal layers in such a manner that respective outside lateral faces of the multiple metal layers are flush with each other, or that outside lateral face of each of the multiple metal layers which is positioned above an underlying metal layer is positioned more inside than outside lateral face of the underlying metal layer; and
the groove has first bottom which is disposed inside the first metal ring and extending to a depth of upper surface of an uppermost metal layer of the first metal ring.

2. The semiconductor device according to claim 1, wherein the groove overlaps the uppermost metal layer, and exposes the upper surface of the uppermost metal layer.

3. The semiconductor device according to claim 1, wherein the first bottom is extending to a depth of lower surface of the uppermost metal layer.

4. The semiconductor device according to claim 1, wherein the uppermost metal layer is exposed on inner surface of the groove, and metal layers of the first metal ring positioned below the uppermost metal layer are not exposed on the inner surface of the groove.

5. The semiconductor device according to claim 1, wherein in the first metal ring, inside lateral face of the uppermost metal layer is disposed more inside than inside lateral faces of metal layers positioned below the uppermost metal layer.

6. The semiconductor device according to claim 4, wherein the metal layers of the first metal ring positioned below the uppermost metal layer are formed of material containing copper.

7. The semiconductor device according to claim 1, wherein a second metal ring is formed above the uppermost metal layer, via insulation member.

8. The semiconductor device according to claim 7, wherein the second metal ring is exposed on inner surface of the groove, while the first metal ring is not exposed on the inner surface of the groove.

9. The semiconductor device according to claim 7, wherein inside lateral face of the second metal ring is disposed more inside than inside lateral faces of metal layers forming the first metal ring.

10. The semiconductor device according to claim 8, wherein metal layers forming the first metal ring are formed of material containing copper.

11. The semiconductor device according to claim 1, wherein
a wiring electrically connected with the semiconductor element and formed by laminating multiple metal layers is provided, and
the uppermost metal layer of the first metal ring is lower than an uppermost metal layer of the wiring.

12. The semiconductor device according to claim 1, wherein
a third metal ring is provided to surround the first metal ring, and the third metal ring is formed by laminating multiple metal layers in such a manner that respective outside lateral faces of the multiple metal layers are flush with each other, or that outside lateral face of each of the multiple metal layers which is positioned above an underlying metal layer is positioned more inside than outside lateral face of the underlying metal layer.

13. A method for producing a semiconductor device comprising:
forming a semiconductor element on a semiconductor substrate;
forming laminated metal layers and laminated insulation films, in such a manner that the laminated insulation films have the laminated metal layers disposed therein, and that the laminated metal layers include a wiring and a first metal ring, the wring is electrically connected with the semiconductor element, and the first metal ring surrounds the semiconductor element; and
forming a groove in the insulation films;
wherein:
the first metal ring is formed of ring metal layers in such a manner that respective outside lateral faces of the ring metal layers are flush with each other, or that outside lateral face of each of the ring metal layers which is positioned above an underlying ring metal layer is positioned more inside than outside lateral face of the underlying ring metal layer; and
the groove is formed to have first bottom which is disposed inside the first metal ring and extending to a depth of upper surface of an uppermost ring metal layer of the first metal ring.

14. The method for producing a semiconductor device according to claim 13, wherein
the first metal ring is formed in such a manner that inside lateral face of the uppermost ring metal layer is disposed more inside than inside lateral faces of ring metal layers positioned below the uppermost ring metal layer, and
the groove is formed in such a manner that the groove overlaps the uppermost ring metal layer, that the uppermost ring metal layer is used as a mask for etching, that the uppermost ring metal layer is exposed on inner surface of the groove, and that ring metal layers positioned below the uppermost ring metal layer are not exposed on the inner surface of the groove.

15. The method for producing a semiconductor device according to claim 14, wherein the ring metal layers positioned below the uppermost ring metal layer are formed of material containing copper.

16. The method for producing a semiconductor device according to claim 13, wherein
the uppermost ring metal layer is lower than an uppermost metal layer of the wiring,
a second metal ring surrounding the semiconductor element is formed using a ring metal layer above the uppermost ring metal layer of the first metal ring, via insulation member,
the second metal ring is formed in such a manner that inside lateral face of the second metal ring is disposed more inside than inside lateral faces of ring metal layers forming the first metal ring, and
the groove is formed in such a manner that the groove overlaps the second metal ring, that the second metal ring is used as a mask for etching, that the second metal ring is exposed on inner surface of the groove, and that the first metal ring is not exposed on the inner surface of the groove.

17. The method for producing a semiconductor device according to claim 16, wherein the ring metal layers forming the first metal ring are formed of material containing copper.

18. The method for producing a semiconductor device according to claim 13, wherein a window for exposing an uppermost metal layer of the wiring is formed simultaneously with the groove.
